(19) United States
(12) Patent Application Publication
(10) Pub. No.: US 2026/0362615 A1
(43) Pub. Date: Nov. 12, 2026

(54) DISPLAY DEVICE

(71) Applicant: LG ELECTRONICS INC., Seoul (KR)

(72) Inventors: Jonggil PYO, Seoul (KR); Chulki KIM, Seoul (KR)

(73) Assignee: LG ELECTRONICS INC., Seoul (KR)

(21) Appl. No.: 19/118,593

(22) PCT Filed: Oct. 5, 2022
(86) PCT No.: PCT/KR2022/015001

§ 371 Date: Apr. 4, 2025

(51) Int. Cl. H05K 5/02

(52) U.S. Cl. CPC H05K 5/0226

(57) ABSTRACT

Disclosed is a display device. The display device disclosed herein comprises: a flexible display panel; a bottom cover which is located behind the display panel and to which the display panel is coupled; a driving module which is located behind the bottom cover and has a moving block that reciprocates; a wing bracket which is adjacent to the driving module and fixed to the rear of the bottom cover; and a wing which extends lengthwise, has one end fixed to the moving block and the other end coupled to the bottom cover, and is pivotably connected, between the one end and the other end, to the wing bracket. The bottom cover faces the rear surface of the display panel and includes a flexible inner plate to which the lateral sides of the display panel are coupled. The inner plate faces the rear surface of the display panel and includes: a flat portion having long sides and short sides; and a forming portion that is formed by being pressed rearward from the flat portion, and extends lengthwise in the longitudinal direction of the short sides.

### TECHNICAL FIELD

The present disclosure relates to a display device.

### BACKGROUND ART

With the development of information society, there has been a growing demand for various types of display devices. In order to meet such demand, various display devices, such as a liquid crystal display (LCD) device, a plasma display panel (PDP), an electro luminescent display (ELD), a vacuum fluorescent display (VFD), an organic light emitting diode (OLED) display, and the like, have been developed and used.

An OLED panel can display an image by depositing an organic layer capable of emitting light on a substrate on which a transparent electrode is formed. OLED panels are not only thin, but also have flexible properties. Research has been actively conducted on the structural characteristics of a display device having such an OLED panel.

### DISCLOSURE

### Technical Problem

It is an object of the present disclosure to solve the above and other problems.

It is another object of the present disclosure to provide a structure that allows the curvature of a display panel to be freely changed.

It is another object of the present disclosure to provide a mechanism that allows the curvature of a display panel to be freely changed.

It is another object of the present disclosure to provide a structure that allows a display panel to be curved with a constant curvature.

### Technical Solution

In accordance with an aspect of the present disclosure, the above and other objects can be accomplished by providing a display device including: a flexible display panel; a bottom cover positioned behind the display panel and to which the display panel is coupled; a driving module disposed at a rear of the bottom cover, the driving module including a moving block configured to perform a reciprocating motion; a wing bracket adjacent to the driving module and fixed to the rear of the bottom cover; and a wing elongated with a first end fixed to the moving block and a second end coupled to the bottom cover, the wing being pivotably coupled to the wing bracket between the first end and the second end, wherein the bottom cover includes an inner plate facing a rear surface of the display panel and to which a lateral side of the display panel is coupled, and wherein the inner plate includes: a plate part facing the rear surface of the display panel and having a long side and a short side; and a forming part formed by being pressed rearward from the plate part, the forming part being elongated in a longitudinal direction of the short side.

### Advantageous Effects

A display device according to the present disclosure has the following effects.

According to at least one of the embodiments of the present disclosure, it is possible to provide a structure that allows the curvature of a display panel to be freely changed.

According to at least one of the embodiments of the present disclosure, it is possible to provide a mechanism that allows the curvature of a display panel to be freely changed.

According to at least one of the embodiments of the present disclosure, it is possible to provide a structure that allows a display panel to be curved with a constant curvature.

Further scope of applicability of the present disclosure will become apparent from the following detailed description. However, it should be understood that the detailed description and specific embodiments such as preferred embodiments of the present disclosure are given by way of example only, since various changes and modifications within the idea and scope of the present disclosure may be clearly understood by those skilled in the art.

### BRIEF DESCRIPTION OF DRAWINGS

FIGS. 1 to 39 are diagrams illustrating examples of a display device according to embodiments of the present disclosure.

### MODE FOR THE INVENTION

Description will now be given in detail according to exemplary embodiments disclosed herein, with reference to the accompanying drawings. For the sake of brief description with reference to the drawings, the same or equivalent components may be denoted by the same reference numbers, and description thereof will not be repeated.

In the following description, suffixes such as “module” and “unit” may be used to refer to elements or components. Use of such suffixes herein is merely intended to facilitate description of the specification, and the suffixes do not have any special meaning or function. In the present disclosure, that which is well known to one of ordinary skill in the relevant art has generally been omitted for the sake of brevity. The accompanying drawings are used to help easily understand the technical idea of the present disclosure and it should be understood that the idea of the present disclosure is not limited by the accompanying drawings. The idea of the present disclosure should be construed to extend to any alterations, equivalents, and substitutes besides the accompanying drawings.

Although the terms “first”, “second”, etc. may be used herein to describe various elements, these elements should not be limited by these terms. These terms are only used to distinguish one element from another.

It will be understood that when a component is referred to as being “coupled” or “connected” to another component, it may be directly coupled or connected to another component, or intervening components may be present. In contrast, when a component is referred to as being “directly coupled” or “directly connected” to another component, there are no intervening components present.

As used herein, a singular representation is intended to include a plural representation unless the context clearly indicates otherwise.

It will be further understood that the terms “comprises or includes” and/or “has” when used in this specification, specify the presence of a stated feature, number, step, operation, component, element, or combination thereof, but do not preclude the presence or addition of one or more other features, numbers, steps, operations, components, elements, or combinations thereof.

Hereinafter, a display panel will be described using an organic light emitting diode (OLED) panel as an example, but the display panel applicable to the present disclosure is not limited to the OLED panel.

In the following description, a display device may include a first long side LS1, a second long side LS2 opposite the first long side LS1, a first short side SS1 adjacent to one end of the first long side LS1 and one end of the second long side LS2, and a second short side SS2 opposite the first short side SS1.

Here, an area of the first short side SS1 may be referred to as a first side area; an area of the second short side SS2 may be referred to as a second side area opposite the first side area; an area of the first long side LS1 may be referred to as a third side area that is adjacent to the first side area and the second side area and positioned between the first side area and the second side area; and an area of the second long side LS2 may be referred to as a fourth side area that is adjacent to the first side area and the second side area, positioned between the first side area and the second side area, and opposite the third side area.

For ease of explanation, it is illustrated and described that lengths of the first and second long sides LS1 and LS2 are greater than lengths of the first and second short sides SS1 and SS2. However, the lengths of the first and second long sides LS1 and LS2 may be substantially equal to the lengths of the first and second short sides SS1 and SS2.

Herein, a first direction DR1 may be a direction parallel to the long sides LS1 and LS2 of the display device, and a second direction DR2 may be a direction parallel to the short sides SS1 and SS2 of the display device. A third direction DR3 may be a direction perpendicular to the first direction DR1 and/or the second direction DR2.

The first direction DR1 and the second direction DR2 may be collectively referred to as a horizontal direction. The third direction DR3 may be referred to as a vertical direction.

A side or a surface on which the display device displays an image may be referred to as a front side or a front surface. When the display device displays an image, a side or a surface at which the image cannot be observed may be referred to as a rear side or a rear surface. When the display device is viewed from the front side or the front surface, the first long side LS1 may be referred to as an upper side or an upper surface. Likewise, the second long side LS2 may be referred to as a lower side or a lower surface. Likewise, the first short side SS1 may be referred to as a left side or a left surface, and the second short side SS2 may be referred to as a right side or a right surface.

The first long side LS1, the second long side LS2, the first short side SS1, and the second short side SS2 may be referred to as edges of the display device. In addition, points where the first long side LS1, the second long side LS2, the first short side SS1, and the second short side SS2 meet one another may be referred to as corners. For example, a point where the first long side LS1 and the first short side SS1 meet may be referred to as a first corner C1; a point where the first long side LS1 and the second short side SS2 meet may be referred to as a second corner C2; a point where the second short side SS2 and the second long side LS2 meet may be referred to as a third corner C3; and a point where the second long side LS2 and the first short side SS1 meet may be referred to as a fourth corner C4.

Herein, a direction from the first short side SS1 to the second short side SS2 or a direction from the second short side SS2 to the first short side SS1 may be referred to as a left-and-right direction LR. A direction from the first long side LS1 to the second long side LS2 or a direction from the second long side LS2 to the first long side LS1 may be referred to as an up-and-down direction UD.

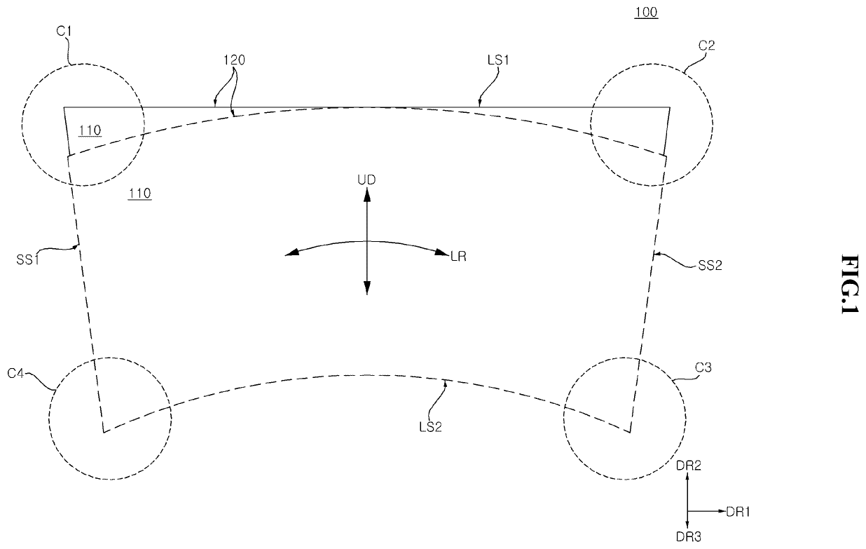

Referring to FIG. 1, a display panel 110 may be coupled to a plate 120. The plate 120 may be flexible. The plate 120 may be referred to as a flexible plate 120, a frame 120, or a module cover 120. The display panel 110 may be positioned in front or on a front surface of the plate 120. The display panel 110 may be flexible. For example, the display panel 110 may be an OLED panel.

The display panel 110 may be provided at the front of a display device 100, and an image may be displayed thereon. The display panel 110 may include a plurality of pixels to output an image in accordance with color, brightness, and chroma of each pixel. The display panel 100 may generate light corresponding to red, green, or blue color in response to a control signal.

The display device 100 may have a variable curvature. The left and right sides of the display device 100 may be configured to move forward. For example, when an image is viewed from the front of the display device 100, the display device 100 may be curved concavely. In this case, the plate 120 may be curved with the same curvature as the display panel 110. Alternatively, the display panel 110 may be curved corresponding to the curvature of the panel 120.

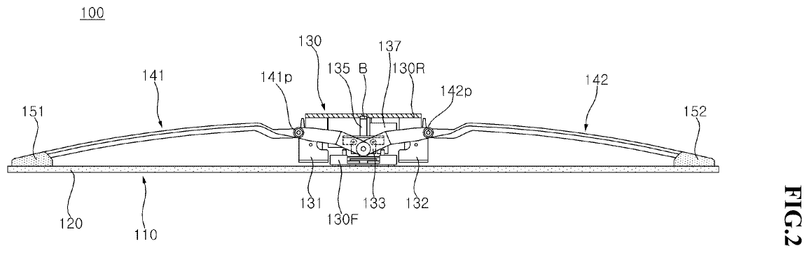

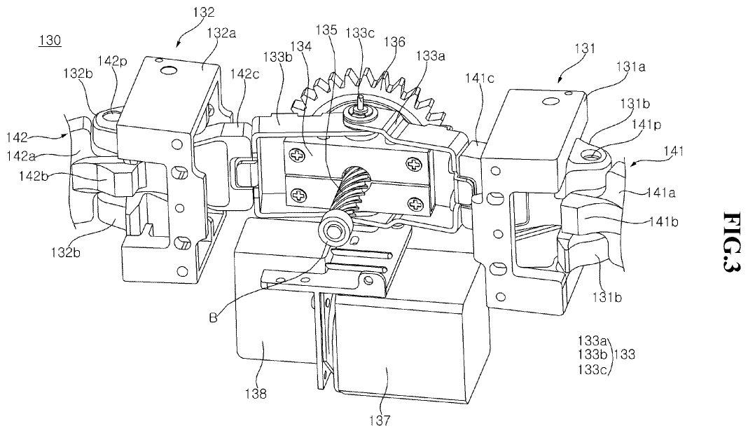

Referring to FIGS. 2 and 3, the plate 120 may be coupled to the rear of the display panel 110. The plate 120 may support the display panel 110 at the rear of the display panel 110. The plate 120 may have a shape corresponding to the display panel 110.

A driving module 130 may be coupled to the rear of the plate 120. A front bracket 130F, a rear bracket 130R, and a wing bracket 131, 132 may be disposed at the rear of the plate 120. The front bracket 130F may be coupled or fixed to a rear surface of the plate 120. The rear bracket 130R may be disposed at the rear of the front bracket 130F, may be spaced apart from the front bracket 130F, and may face the front bracket 130F.

The wing bracket 131, 132 may include a bracket frame 131a, 132a and a wing holder 131b, 132b. The bracket frame 131a, 132a may be in the shape of a rectangular box. The wing holder 131b, 132b may be formed on one side of the bracket frame 131a, 132a. The wing holder 131b, 132b may protrude from one surface of the bracket frame 131a, 132a. A pair of wing holders 131b, 132b may be provided. The pair of wing holders 131b, 132b may be opposite each other.

There may be a plurality of wing brackets 131 and 132. The plurality of wing brackets 131 and 132 may include a first wing bracket 131 and a second wing bracket 132. The first wing bracket 131 may be coupled or fixed to the front bracket 130F and/or the rear bracket 130R, and may be disposed opposite the second wing bracket 132 with respect to the front bracket 130F. The second wing bracket 132 may be coupled or fixed to the front bracket 130F and/or the rear bracket 130R.

A wing 141, 142 may include a blade 141a, 142a, a neck 141b, 142b, and a lever 141c, 142c. For example, the wing 141, 142 may be made of metal. As another example, the wing 141, 142 may be made of an aluminum alloy. The blade 141a, 142a may be an elongated plate and may have a rib to ensure rigidity. The lever 141c, 142c and the neck 141b, 142b may be formed at one end of the blade 141a, 142a. The neck 141b, 142b may be disposed between the lever 141c, 142c and the blade 141a, 142a to connect the lever 141c, 142c and the blade 141a, 142a. A width of the neck 141b, 142b may be less than a width of the lever 141c, 142c, and the width of the lever 141c, 142c may be less than a width of the blade 141a, 142a. A pivot shaft 141p, 142p may be provided at the neck 141b, 142b. The pivot shaft 141p, 142p may be inserted into the wing holder 131b, 132b. The wing 141, 142 may pivot about the pivot shaft 141p, 142p and the wing holder 131b, 132b.

A first wing 141 may be rotatably or pivotably coupled to the first wing bracket 131, and a second wing 142 may be rotatably or pivotably coupled to the second wing bracket 132. The first wing 141 and the second wing 142 may be symmetric with respect to the driving module 130.

A sliding mount 151, 152 may be coupled or fixed to the rear or rear surface of the plate 120. A first sliding mount 151 may be positioned adjacent to a left side of the plate 120, and a second sliding mount 152 may be positioned adjacent to a right side of the plate 120. An end of the first wing 141 may be movably coupled to the first sliding mount 151. An end of the second wing 142 may be movably coupled to the second sliding mount 152.

A flip frame 133 may be disposed between the lever 141c of the first wing 141 and the lever 142c of the second wing 142, and may be coupled to the levers 141c and 142c. For example, the flip frame 133 may be made of metal. The flip frame 133 may include a first frame 133a and a second frame 133b. For example, the first frame 133a may have a U-shape, and the second frame 133b may have a U-shape. The first frame 133a and the second frame 133b may be pivotably connected to each other. A pivot pin 133c may pass through the first frame 133a and the second frame 133b to connect the first frame 133a and the second frame 133b. The first frame 133a may pivot relative to the second frame 133b, and the second frame 133b may pivot relative to the first frame 133a. The first frame 133a may be fixed or coupled to the lever 141c of the first wing 141, and the second frame 133b may be fixed or coupled to the lever 142c of the second wing 142.

A moving block 134 may be positioned inside the flip frame 133. The moving block 134 may be disposed between the first frame 133a and the second frame 133b of the flip frame 133.

A lead screw 135 may be inserted into the moving block 134. As the lead screw 135 rotates, the moving block 134 may move on the lead screw 135. Rotation and reverse rotation of the lead screw 135 may cause the moving block 134 to perform a reciprocating motion along the lead screw 135.

The lead screw 135 may be coupled to a driving gear 136 and may rotate together with the driving gear 136. The driving gear 136 may rotate while facing the rear surface of the plate 120 (see FIG. 2). The lead screw 135 may serve as a rotating shaft of the driving gear 136. A bearing B may be coupled to one end and/or both ends of the lead screw 135. The lead screw 135 may rotate with its one end being inserted into a front bearing B and its other end being inserted into a rear bearing B. For example, the lead screw 135 may be press-fitted into the front bearing B and the rear bearing B.

A motor 137 may be positioned below the moving block 134. The motor 137 may provide torque. A gear box 138 may transmit the torque of the motor 137 to the driving gear 136.

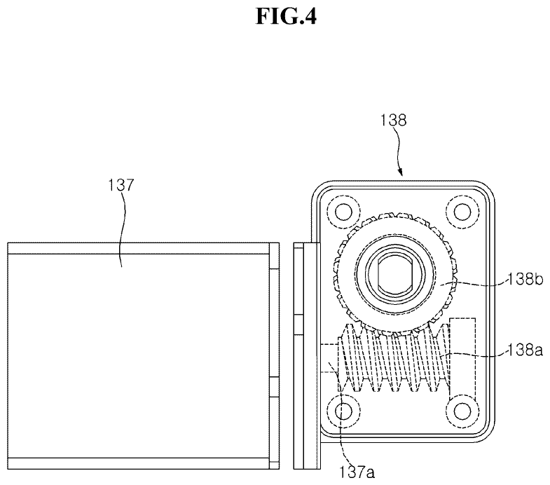

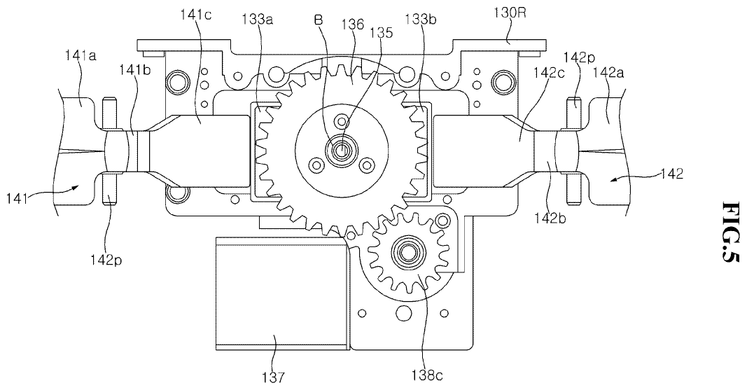

Referring to FIGS. 4 and 5, a first gear 138a may be fixed to a rotating shaft 137a of the motor 137 so as to rotate together with the rotating shaft 137a of the motor 137. For example, the first gear 138a may be a worm. A second gear 138b may mesh with the first gear 138a. For example, the second gear 138b may be a worm gear.

The first gear 138a and the second gear 138b may be disposed inside the gear box 138. A transmission gear 138c may be disposed outside the gear box 138. The transmission gear 138c may be fixed to the rotating shaft 137a of the second gear 138b and may rotate together with the second gear 138b. The transmission gear 138c may mesh with the driving gear 136.

The lead screw 135 may be a rotating shaft of the driving gear 136. The driving gear 136 may be fixed to the lead screw 135. The driving gear 136 may be coupled to the lead screw 135 by a pin.

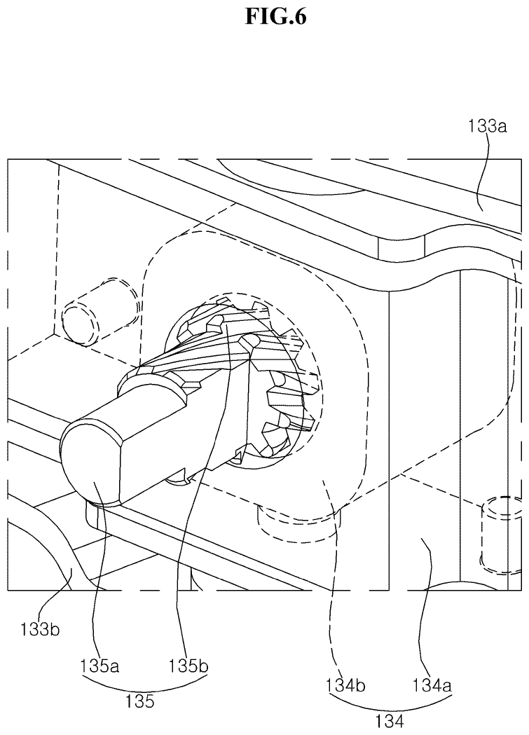

Referring to FIG. 6, the lead screw 135 may include a shaft body 135a and a screw 135b. The shaft body 135a may be in the shape of an elongated cylinder, and the screw 135b may be formed on an outer circumferential surface of the shaft body 135a. The moving block 134 may include a moving body 134a and a sliding block 134b. For example, the moving body 134a may be made of metal, and the sliding block 134b may be made of a synthetic resin. The sliding block 134b may be disposed inside the moving body 134a. The sliding block 134b may be screw-coupled to the lead screw 135.

The lead screw 135 may be inserted into the sliding block 134b. As the lead screw 135 rotates, the sliding block 134b may move on the lead screw 135. A clearance may be formed between an inner circumferential surface of the sliding block 134b and the screw 135b of the lead screw 135. Accordingly, the moving block 134 may be prevented from being caught or locked while moving on the lead screw 135.

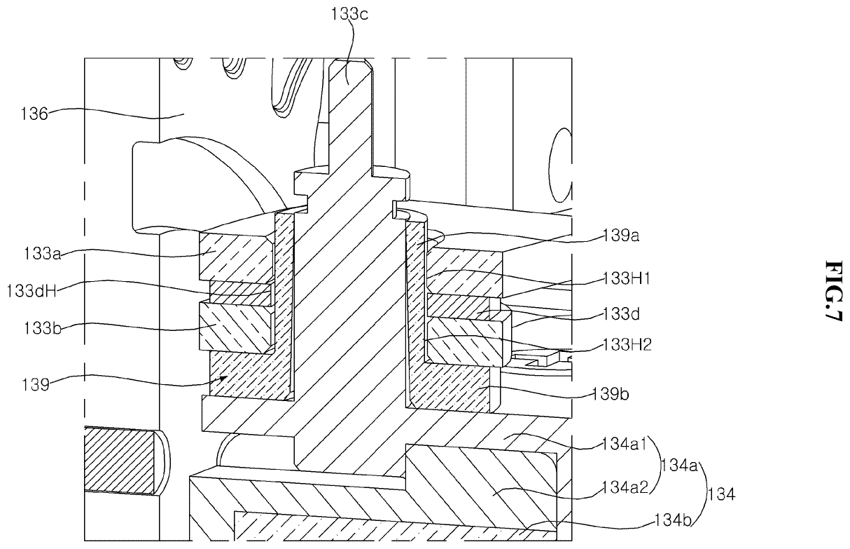

Referring to FIG. 7, the moving body 134a may include an outer part 134a1 and an inner part 134a2. The outer part 134a1 may define an outer surface of the moving body 134a. The inner part 134a2 may be coupled to the inside of the outer part 134a1. For example, the outer part 134a1 may be a U-shaped metal plate, and the inner part 134a2 may be a metal shell having an accommodation space therein. The sliding block 134b may be coupled to the inside of the inner part 134a2.

The pivot pin 133c may protrude and extend from the outer part 134a1 of the moving body 134a. The first frame 133a and the second frame 133b of the flip frame 133 may include holes 133H1 and 133H2. The pivot pin 133c may be inserted into the hole 133H2 of the second frame 133b and the hole 133H1 of the first frame 133a. A disc 133d may be disposed between the first frame 133a and the second frame 133b, and the pivot pin 133c may be inserted into a hole 133dH of the disc 133d. For example, the disc 133d may be made of a material with high durability and low friction.

An intermediate member 139 may be disposed between the moving body 134a, the pivot pin 133c, and the flip frame 133. The intermediate member 139 may cover an upper surface of the moving body 134a and an outer surface of the pivot pin 133c. The intermediate member 139 may be referred to as a low friction member 139 or a lubricating member 139. The intermediate member 139 may also be referred to as a skin member 139.

The intermediate member 139 may include a body portion 139a and a flange portion 139b. The body portion 139a may have a cylindrical shape. The pivot pin 133c may be inserted into the body portion 139a. The body portion 139a may be in contact with the outer surface of the pivot pin 133c, and the flange portion 139b may be in contact with the upper surface of the moving body 134a. The intermediate member 139 may be made of a synthetic resin with low friction. The intermediate member 139 may be made of a low-friction material. For example, the intermediate member 139 may be made of POM acetal homopolymer. The first frame 133a and the second frame 133b of the flip frame 133 may move about the pivot pin 133c while making contact with or rubbing against the intermediate member 139.

The intermediate member 139 may fill a gap between the pivot pin 133c and the hole 133H1 of the first frame 133a of the flip frame 133. The intermediate member 139 may fill a gap between the pivot pin 133c and the hole 133H2 of the second frame 133b of the flip frame 133. The second frame 133b of the flip frame 133 may be placed on the intermediate member 139. Accordingly, the pivot pin 133c may transmit force to the flip frame 133 without causing noise or vibration.

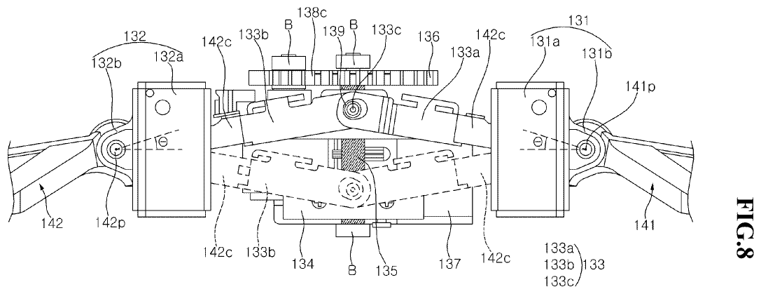

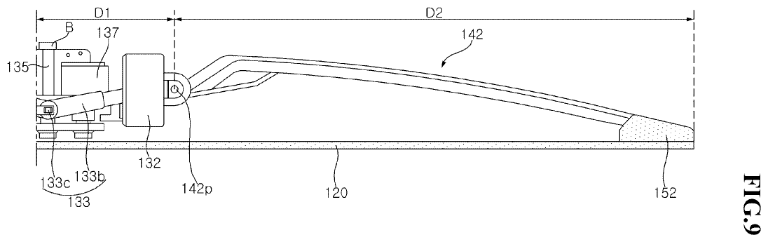

Referring to FIGS. 8 and 9, when the lead screw 135 rotates, the moving block 134 and the flip frame 133 may move on the lead screw 135. The flip frame 133 may reciprocate in a longitudinal direction of the lead screw 135. The movement of the flip frame 133 may cause the first wing 141 and/or the second wing 142 to pivot about the pivot shaft 141P, 142P.

A first distance D1 from the pivot pin 133c to the pivot shaft 141P, 142P may be less than a second distance D2 from the pivot shaft 141P, 142P to the sliding mount 151, 152. For example, the first distance D1 may be one-fourth (¼) of the second distance D1. As the lever 141c, 142c of the wing 141, 142 are fixed to the flip frame 133, and the flip frame 133 moves together with the pivot pin 133c, a driving force of the moving block 134 moving on the lead screw 135 may be efficiently transmitted to the lever 141c, 142c of the wing 141, 142 through the flip frame 133.

In addition, as the lever 141c, 142c of the wing 141, 142 are fixed to the flip frame 133 and move together with the flip frame 133, the first distance D1 increases, such that less force is required to drive the wings 141 and 142. Thus, it is possible to increase power transmission efficiency of the driving unit 130 and to reduce power consumption of the motor 137.

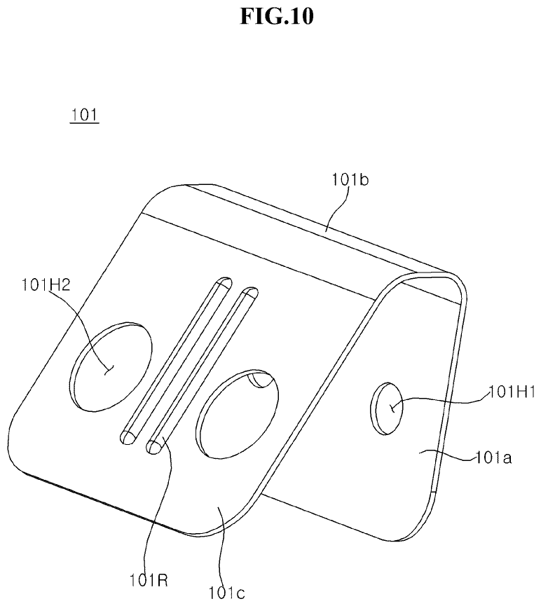

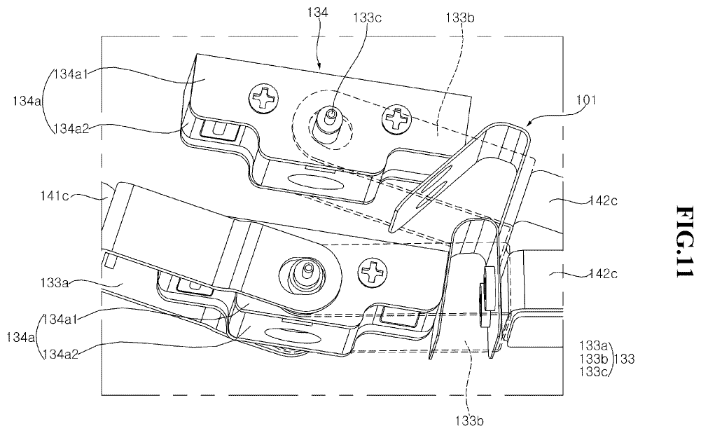

Referring to FIGS. 10 and 11, an elastic member 101 may include a first part 101a, a second part 101b, and a third part 101c. The elastic member 101 may be referred to as a first elastic member 101 or a clip 101. The first part 101a may be a plate. The second part 101b may be bent and extend from the first part 101a. The third part 101c may be bent and extend from the second part 101b. The third part 101c may face the first part 101a. A second angle formed by the second part 101b and the third part 101c may be greater than a first angle formed by the first part 101a and the second part 101b. In the extending direction, the third part 101c may be greater in length than the first part 101a. The elastic member 101 may be a metal plate and may have elasticity. For example, the elastic member 101 may be a leaf spring.

A coupling hole 101H1 may be formed in the first part 101a. The coupling hole 101H1 may be provided in plurality. A support rib 101R may be formed on the third part 101c. The support rib 101R may be elongated in the direction in which the third part 101c extends. The support rib 101R may be provided in plurality. The support rib 101R may protrude from an outer surface of the third part 101c. The plurality of support ribs 101R may be parallel to each other.

The elastic member 101 may be inserted between the moving block 134 and the lever 141c, 142c of the wing 141, 142. The first part 101a of the elastic member 101 may be fixed to the lever 141c, 142c of the wing 141, 142. For example, the first part 101a of the elastic member 101 may be screw-coupled to the lever 141c, 142c of the wing 141, 142. The third part 101c of the elastic member 101 may support the moving block 134. The third part 101c of the elastic member 101 may be in contact with a side surface of the moving block 134. The third part 101c of the elastic member 101 may be in contact with the outer part 134a1 and/or the inner part 134a2 of the moving body 134a. The outer part 134a1 and/or the inner part 134a2 of the moving body 134a in contact with the third part 101c of the elastic member 101 may be rounded. The support rib 101R formed on the third part 101c of the elastic member 101 may be in contact with the inner part 134a2 of the moving block 134.

A plurality of elastic members 101 may be provided. The plurality of elastic members 101 may be inserted between the moving block 134 and the lever 141c of the first wing 141 and between the moving block 134 and the lever 142c of the second wing 142, respectively.

In a mechanism in which the flip frame 133 flips or pivots about the pivot pin 133c, a clearance may be formed between the pivot pin 133c of the moving block 134 and the hole 133H1, 133H2 (see FIG. 7) of the flip frame 133. The elastic member 101 may push the moving block 134 in one direction. As the elastic member 101 pushes the moving block 134 in one direction, the pivot pin 133c of the moving block 134 may be pressed against one side of the hole 133H1, 133H2 of the flip frame 133.

Accordingly, force may be transmitted to the flip frame 133 in the entire region where the moving block 134 moves on the lead screw 135. In a mechanism in which the moving block 134 transmits force to the flip frame 133, bending of the display panel 110 may be temporarily interrupted by a clearance between the components. In this embodiment, continuous bending of the display panel 110 may be achieved.

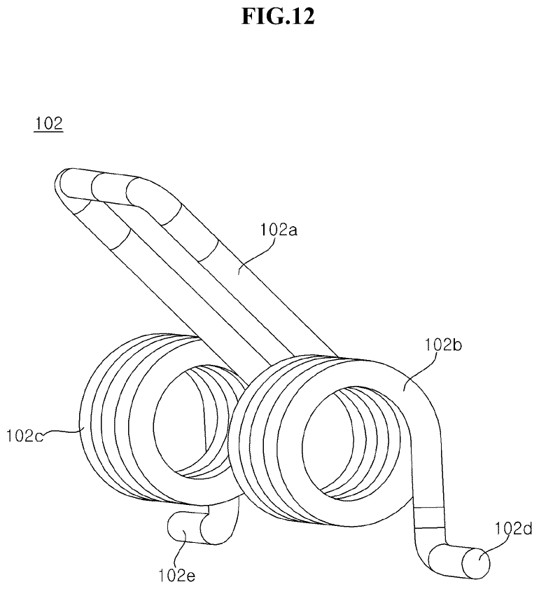

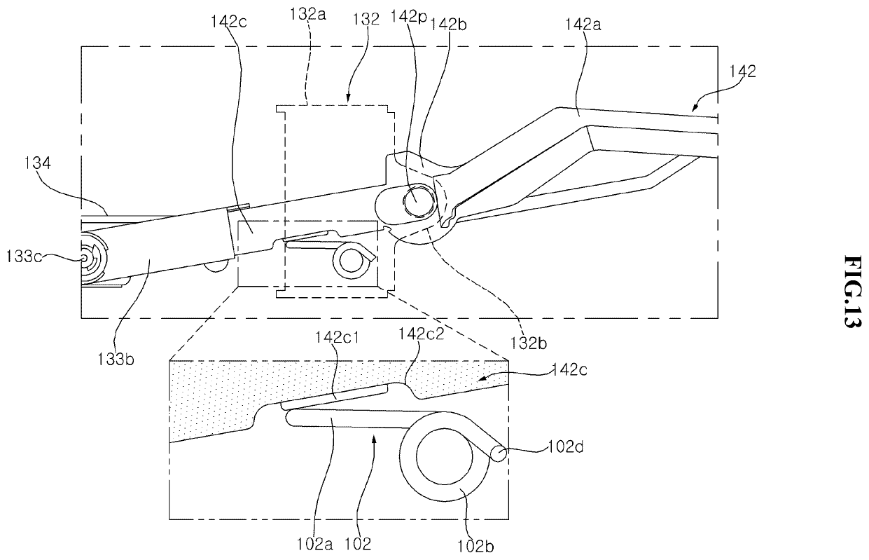

Referring to FIGS. 12 and 13, an elastic member 102 may include a lever portion 102a, a support portion 102d, 102e, and a coil portion 102b, 102c. The elastic member 102 may be configured as a wire. The elastic member 102 may be referred to as a second elastic member 102.

The lever portion 102a may be a wire bent in a U-shape. The coil portion 102b, 102c may be connected to the lever portion 102a. There may be a plurality of coil portions 102b and 102c. A first coil portion 102b may be connected to one end of the lever portion 102a, and a second coil portion 102c may be connected to the other end of the lever portion 102a. There may be a plurality of support portions 102d and 102e. A first support portion 102d may form an end of the first coil portion 102b, and a second support portion 102e may form an end of the second coil portion 102c.

When the support portions 102d and 102e are fixed, the lever portion 102a may rotate or pivot about the coil portions 102b and 102c. The coil portions 102b and 102c may provide elasticity to the lever portion 102a.

The elastic member 102 may be installed on the wing bracket 132. The support portions 102d and 102e of the elastic member 102 may be fixed to the bracket frame 132a of the wing bracket 132. The lever portion 102a of the elastic member 102 may be supported by the lever 142c of the wing 142.

The wing 142 may include a support groove 142c2 and a friction pad 142c1. The support groove 142c2 may be formed at a position corresponding to a portion of a length of the lever portion 102a of the elastic member 102. The friction pad 142c1 may be formed on the support groove 142c2. The friction pad 142c1 may protrude from the support groove 142c2 and its surface may be smoothly polished.

When the wing 141, 142 is pivotably coupled to the wing bracket 131, 132, a clearance may be formed between the pivot shaft 141p, 142p of the wing 141, 142 and the wing holder 131b, 132b of the wing bracket 131, 132. In a mechanism in which the moving block 134 transmits force to the flip frame 133 to allow the wings 141 and 142 to bend the display panel 110, bending of the display panel 110 may be temporarily interrupted by the clearance between the components. The wing 141, 142 may receive force from the elastic member 102 in a forward direction of the display device 100, thereby allowing for continuous bending of the display panel 110. Also, it is possible to reduce power consumption of the motor 137 required to bend the display panel 110.

In addition, as the sliding block 134b (see FIG. 6) is screw-coupled to the lead screw 135, a clearance for the sliding block 134b to move on the lead screw 135 may be formed. As the elastic member 102 pushes the wing 141, 142 to press the sliding block 134b in one direction of the lead screw 135, continuous bending of the display panel 110 may be achieved. Further, when the torque of the motor 137 and the lead screw 135 is released while the display panel 100 is in a flat state, flatness of the display panel 110 may be changed. In this embodiment, the display panel 110 may remain flat and/or curved with a predetermined curvature.

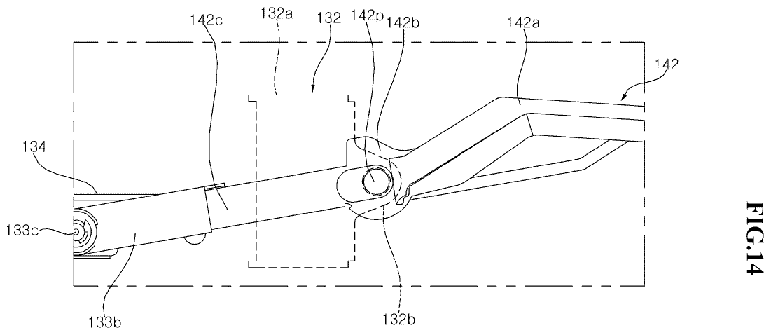

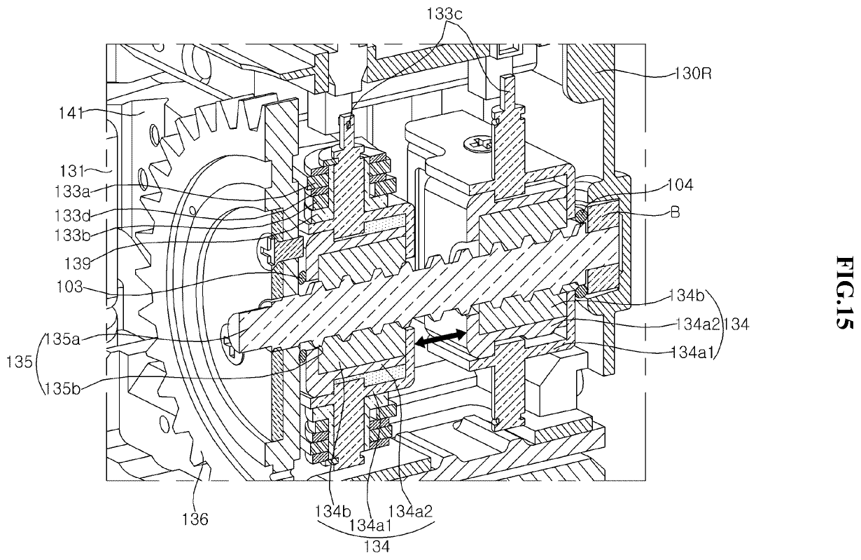

Referring to FIGS. 14 and 15 along with FIG. 8, when the wing 141, 142 is pivotably coupled to the wing bracket 131, 132, a clearance may be formed between the pivot shaft 141p, 142p of the wing 141, 142 and the wing holder 131b, 132b of the wing bracket 131, 132. In a mechanism in which the moving block 134 transmits force to the flip frame 133 to allow the wing 141, 142 to bend the display panel 110, the bending of the display panel 110 may be temporarily interrupted by the clearance between the components.

An elastic ring 103, 104 may be disposed around an outer circumference of the lead screw 135. The lead screw 135 may be inserted into the elastic ring 103, 104. The elastic ring 103, 104 may be referred to as a compression ring 103, 104, or a compression member 103, 104. For example, the elastic ring 103, 104 may be highly elastic rubber. A diameter of the elastic ring 103, 104 may be greater than a diameter of the shaft body 135a of the lead screw 135. For example, an inner diameter of the of the elastic ring 103, 104 may be greater than an outer diameter of the shaft body 135a of the lead screw 135. There may be a plurality of elastic rings 103 and 104. The plurality of elastic rings 103 and 104 may include a first elastic ring 103 and a second elastic ring 104. The first elastic ring 103 may be referred to as a front elastic ring 103, and the second elastic ring 104 may be referred to as a rear elastic ring 104.

The front elastic ring 103 may be disposed between the driving gear 136 and the moving block 134. The front elastic ring 103 may be in contact with the driving gear 136. As the moving block 134 moves on the lead screw 135, the front elastic ring 103 may come into contact with or be spaced apart from the inner part 134a2 of the moving block 134. As the moving block 134 approaches the driving gear 136, the moving block 134 may compress the front elastic ring 103. In addition, when the moving block 134 moves away from the driving gear 136, the front elastic ring 103 may push the moving block 134.

The rear elastic ring 104 may be disposed between the bearing B and the moving block 134. The rear elastic ring 104 may be in contact with the bearing B. As the moving block 134 moves on the lead screw 135, the rear elastic ring 104 may come into contact with or be spaced apart from the outer part 134a1 of the moving block 134. As the moving block 134 approaches the bearing B, the moving block 134 may compress the rear elastic ring 104. In addition, when the moving block 134 moves away from the bearing B, the rear elastic ring 104 may push the moving block 134.

Accordingly, it is possible to achieve continuous bending of the display panel 110. In addition, a large amount of power consumption may be required during initial driving to bend or flatten the display panel 110. As the elastic ring 103, 104 pushes the moving block 134 when the moving block 134 is initially driven, it is possible to reduce power consumption of the motor 137 required to bend the display panel 110.

In addition, as the sliding block 134b (see FIG. 6) is screw-coupled to the lead screw 135, a clearance for the sliding block 134b to move on the lead screw 135 may be formed. As the moving block 134 compresses the elastic ring 103, 104 or the elastic ring 103, 104 pushes the moving block 134 so that the sliding block 134b comes into close contact with the lead screw 135 in the longitudinal direction of the lead screw 135, it is possible to achieve continuous bending of the display panel 110.

Further, when the torque of the motor 137 and the lead screw 135 is released while the display panel 110 is in a flat state, the flatness of the display panel 110 may be changed. In this embodiment, the display panel 110 may remain flat and/or curved with a predetermined curvature.

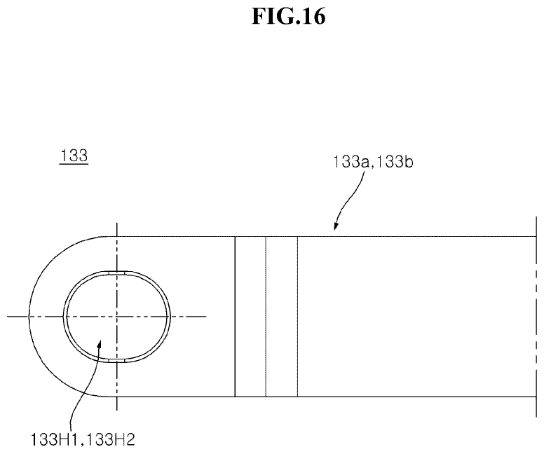

Referring to FIG. 16, the flip frame 133 may have the hole 133H1, 133H2. The hole 133H1, 133H2 may be positioned adjacent to an end of the first frame 133a and/or the second frame 133b of the flip frame 133. The hole 133H1, 133H2 may be a long hole 133H1, 133H2 having a major axis and a minor axis. The major axis of the hole 133H1, 133H2 may be parallel to a longitudinal direction of the frame 133. The minor axis of the hole 133H1, 133H2 may intersect the longitudinal direction of the frame 133.

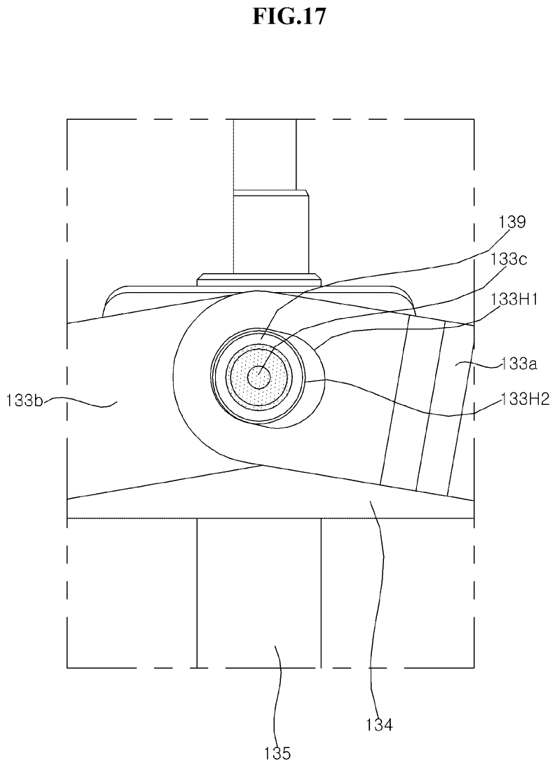

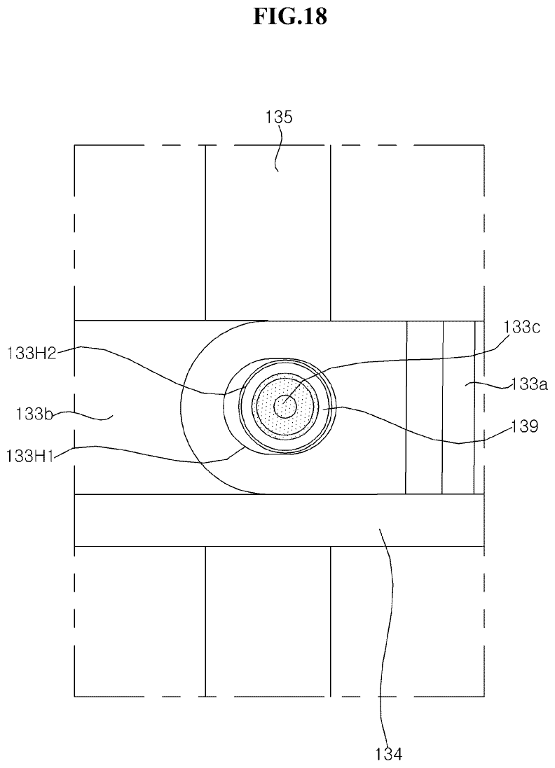

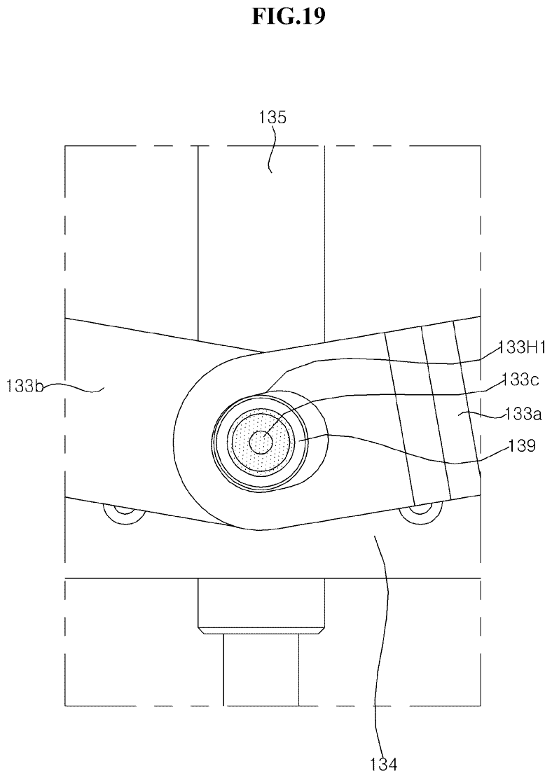

Referring to FIGS. 17 to 19, the pivot pin 133c may be inserted into the holes 133H1 and 133H2 of the flip frame 133, and the moving block 134 may move on the lead screw 135. As the moving block 134 moves on the lead screw 135, the display panel 110 in a flat state (see FIG. 17) may be curved (see FIG. 18) to be in a curved state in which the display panel 110 is curved with a constant curvature (see FIG. 19).

When the display panel 110 starts to be curved from a flat state or when the display panel 110 curved with a predetermined curvature becomes flat as a radius of curvature becomes greater than a predetermined radius of curvature, a moving direction of the moving block 134 may be changed. That is, at a start point and an end point of the moving block 134, the display panel 110 may be flat or curved with a predetermined curvature.

When the moving direction of the moving block is changed at the start point and/or the end point, a direction in which the pivot pin 133c applies force to the holes 133H1 and 133H2 of the flip frame 133 may be changed. As the direction in which the pivot pin 133c applies force to the holes 133H1 and 133H2 of the flip frame 133 is changed, the clearance between the pivot pin 133c and the hole 133H1, 133H2 of the flip frame 133 may cause a break or stop in the continuity of change in curvature of the display panel 110.

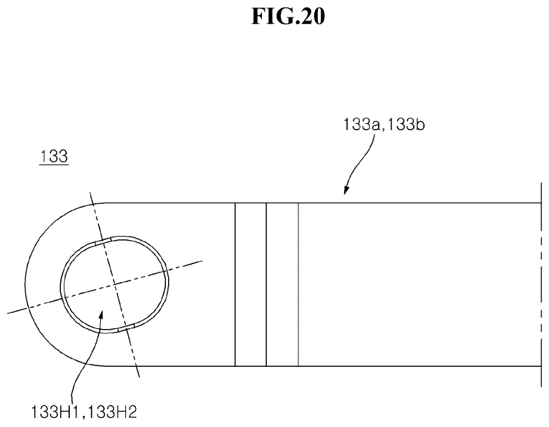

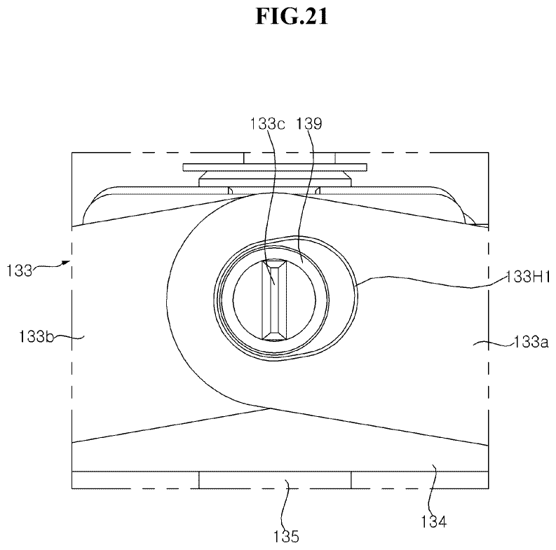

Referring to FIGS. 20 and 21, the major axis of the hole 133H1, 133H2 of the flip frame 133 may form an angle θ with respect to a longitudinal direction of the flip frame 133. For example, the angle θ may correspond to an angle θ formed by the start point or the end point of the moving block 134 and the pivot shaft 141p, 142p of the wing 141, 142 (see FIG. 8) with respect to a line connecting the pivot shafts 141p and 142p of the wings 141 and 142.

As the holes 133H1 and 133H2 of the flip frame 133 approach the start point or the end point of the moving block 134, the major axis of the hole 133H1, 133H2 may become parallel to a reference line connecting the pivot shafts 141p and 142p of the wings 141 and 142 of the moving block 134. When a moving direction of the pivot pin 133c is changed, the moving direction of the pivot pin 133c may be aligned with a direction of the minor axis of the hole 133H1, 133H2 of the flip frame 133.

When the moving direction of the pivot pin 133c is aligned with the minor axis of the hole 133H1, 133H2 of the flip frame 133 as the moving direction of the pivot pin 133c is changed, the clearance formed between the pivot pin 133c and the hole 133H1, 133H2 may be minimized. Accordingly, by the movement and/or direction change of the moving block 134, the pivot pin 133c may continuously transmit power or force to the flip frame 133.

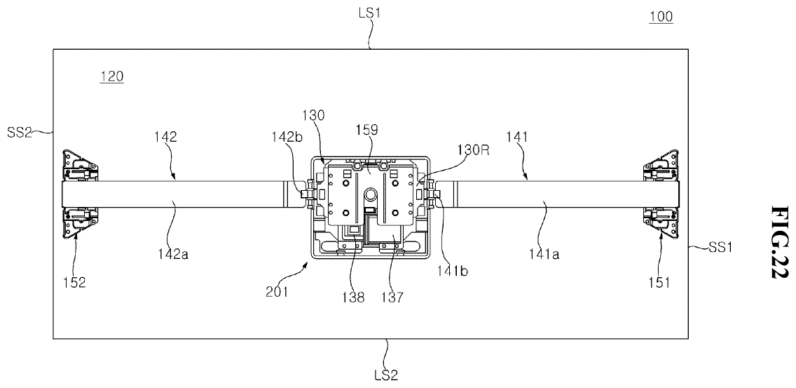

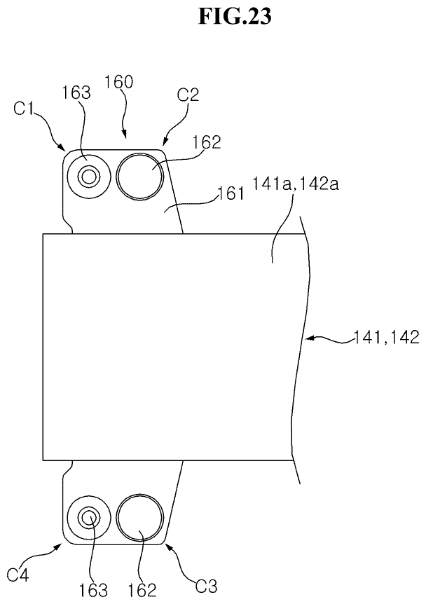

Referring to FIGS. 22 and 23, the first sliding mount 151 may be fixed to the rear surface of the plate 120 while being adjacent to the first short side SS1 of the plate 120. A second sliding mount 152 may be fixed to the rear surface of the plate 120 while being adjacent to the second short side SS2 of the plate 120.

The driving module 130 may be disposed between the first sliding mount 151 and the second sliding mount 152, and may be coupled to the rear surface of the plate 120. The first wing 141 may have one end (or a first end) pivotably connected to the driving module 130 and the other end (or a second end) coupled to the first sliding mount 151. The second end of the first wing 141 may move on the first sliding mount 151. The second wing 142 may have one end (or a first end) pivotably connected to the driving module 130 and the other end (or a second end) coupled to the second sliding mount 152. The second end of the second wing 142 may move on the second sliding mount 152.

A PCB plate 159 may be disposed at the rear of the driving module 130. The PCB plate 159 may be fixed to the rear bracket 130R (see FIG. 2) of the driving module 130. Printed circuit boards (PCBs) may be coupled to the PCB plate 159.

A side cover 201 may form a wall around the sides of the driving module 130. For example, the side cover 201 may be a quadrangular frame. A back cover (not shown) may be coupled to the side cover 201 while covering the driving module 130.

A slide bracket 160 may be coupled or fixed to an end of the wing 141, 142. The slide bracket 160 may include a body 161 having an elongated plate shape and a protrusion 162, 163 formed adjacent to both ends of the body 161. The protrusion 162, 163 may be referred to as a friction protrusion 162, 163 or a contact protrusion 162, 163. For example, the slide bracket 160 may be made of metal.

There may be a plurality of protrusions 162 and 163. The plurality of protrusions 162 and 163 may include a front protrusion 163 and a rear protrusion 162. The front protrusion 163 may be formed at a first corner C1 and/or a fourth corner C4 of the body 161. The front protrusion 163 may protrude by being pressed toward the front of the body 161. The front protrusion 163 may have a dome or hemispherical shape. The rear protrusion 162 may be formed at a second corner C2 and/or a third corner C3 of the body 161. The rear protrusion 162 may protrude by being pressed toward the rear of the body 161. The rear protrusion 162 may have a dome or hemispherical shape. The rear protrusion 162 may be adjacent to the front protrusion 163. The front protrusion 163 and the rear protrusion 162 may be sequentially disposed along a short side of the body 161. One pair of the front protrusion 163 and the rear protrusion 162 may be disposed opposite another pair of the front protrusion 163 and the rear protrusion 162 with respect to the wing 141, 142.

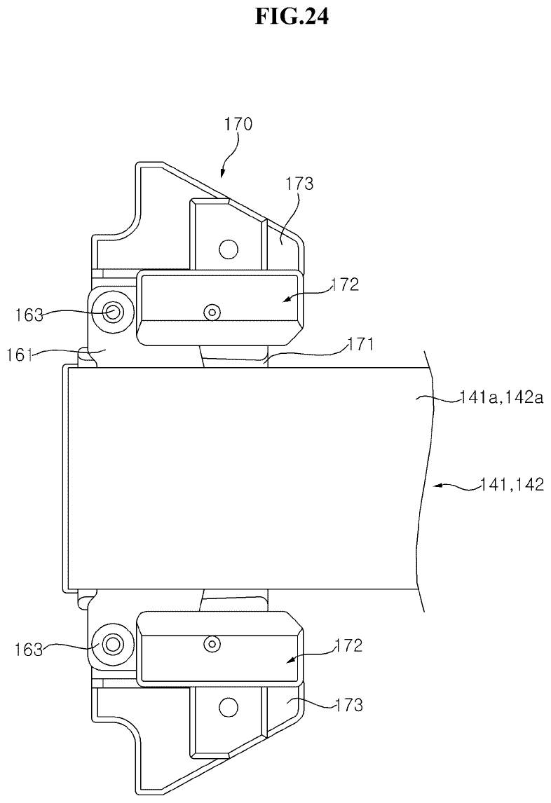

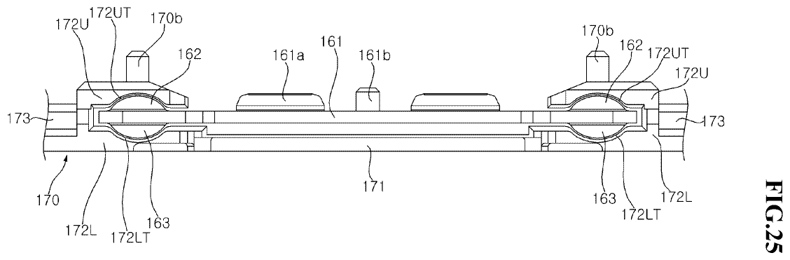

Referring to FIGS. 24 and 25, the slide bracket 160 may be coupled to a guide cover 170. The slide bracket 160 may be inserted into the guide cover 170, and may be movable on the guide cover 170. For example, the guide cover 170 may be made of a synthetic resin with low friction. The guide cover 170 may be made of a low-friction material. For example, the guide cover 170 may be made of POM acetal homopolymer.

The guide cover 170 may include a base 171, a side rail 172, and a fixing plate 173. The base 171 may have an elongated plate shape and may face the slide bracket 160. The side rail 172 may be provided at both ends of the base 171. The side rail 172 may include a lower part 172L and an upper part 172U. The lower part 172L may extend from the base 171.

The lower part 172L may be provided with a lower trench 172LT. The lower trench 172LT may be formed in the lower part 172L as an upper surface of the lower part 172L is recessed inward in an elongated manner. For example, the lower trench 172LT may be in the shape of a half pipe. The front protrusion 163 of the slide bracket 160 may move on the lower trench 172LT. A radius of curvature of the front protrusion 163 may be less than a radius of curvature of the lower trench 172LT, thereby allowing the front protrusion 163 to make point contact with the lower trench 172LT.

The upper part 172U may be spaced apart from the lower part 172L and may face the lower part 172L. A gap may be formed between the upper part 172U and the lower part 172L, and the slide bracket 160 may be inserted into the gap. The upper part 172U may be provided with an upper trench 172UT. The upper trench 172UT may be formed in the upper part 172U as a lower surface of the upper part 172U is recessed inward in an elongated manner. For example, the upper trench 172UT may be in the shape of a half pipe. The rear protrusion 162 of the slide bracket 160 may move on the upper trench 172UT. A radius of curvature of the rear protrusion 162 may be less than a radius of curvature of the upper trench 172UT, thereby allowing the rear protrusion 162 to make point contact with the upper trench 172UT.

As the slide bracket 160 and the guide cover 170 are coupled to each other, it is possible to prevent deflection or sagging of the wing 141, 142 due to self-weight.

The slide bracket 160 may include a coupling portion 161a and a PEM nut 161b or a coupling protrusion 161b for coupling with the wing 141, 142. The guide cover 170 may include a PEM nut 170b or a coupling protrusion 170b for coupling with the sliding mount 151, 152.

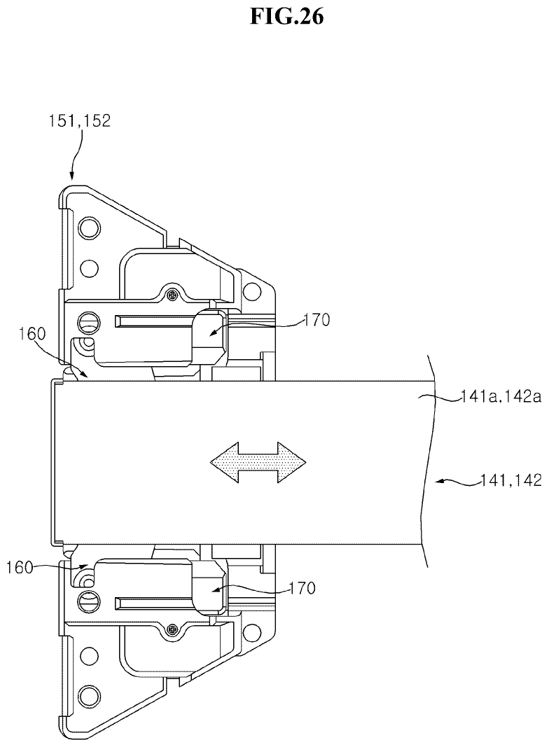

Referring to FIGS. 26 to 28, the slide bracket 160 may be coupled to a front surface of the wing blade 141a, 142b while being adjacent to an end of the wing 141, 142. The guide cover 170 may be fixed to the sliding mount 151, 152. The slide bracket 160 may be inserted into the guide cover 170, and may move on the guide cover 170 while reciprocating in a longitudinal direction of the wing 141, 142.

When the display panel 110 transitions from a curved state with a predetermined curvature to a flat state, the slide bracket 160 may move on the guide cover 170 toward the short side SS1, SS2 of the plate 120. The front protrusion 163 may move on the lower trench 172LT. The front protrusion 163 may move on the lower trench 172LT while making contact with or gently rubbing against the surface of the lower trench 172LT. The rear protrusion 162 may move on the upper trench 172UT while making contact with or gently rubbing against the surface of the upper trench 172UT.

When the display panel 110 transitions from a flat state to a curved state with a predetermined curvature, the slide bracket 160 may move on the guide cover 170 from the short side SS1, SS2 of the plate 120 toward the driving module 130. The front protrusion 163 may move on the lower trench 172LT. The front protrusion 163 may move on the lower trench 172LT while making contact with or gently rubbing against the surface of the lower trench 172LT. The rear protrusion 162 may move on the upper trench 172UT while making contact with or gently rubbing against the surface of the upper trench 172UT.

As the protrusion 162, 163 makes point contact with the trench 172LT, 172UT, it is possible to reduce friction to thereby reduce abrasion caused by friction. In addition, as no lubricant is required, it is possible to improve structural durability of the mechanism.

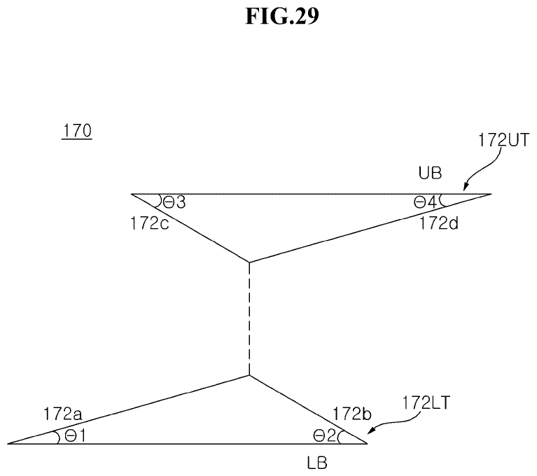

Referring to FIG. 29, the lower trench 172LT may include a first inclined surface 172a and a second inclined surface 172b, and the upper trench 172UT may include a third inclined surface 172c and a fourth inclined surface 172d. The first inclined surface 172a may form a first angle θ1 with respect to a base surface LB. The second inclined surface 172b may form a second angle θ2 with respect to the base surface LB. The second inclined surface 172b may be in contact with the first inclined surface 172a.

The third inclined surface 172c may form a third angle 03 with respect to a base surface UB. The fourth inclined surface 172d may form a fourth angle θ4 with respect to the base surface UB. The fourth inclined surface 172d may be in contact with the third inclined surface 172c. A boundary between the third inclined surface 172c and the fourth inclined surface 172d may correspond to or be aligned with a boundary between the first inclined surface 172a and the second inclined surface 172b. For example, the boundary between the third inclined surface 172c and the fourth inclined surface 172d and the boundary between the first inclined surface 172a and the second inclined surface 172b may be vertically aligned on the same line.

The second angle θ2 may be greater than the first angle θ1. The third angle 03 may be greater than the fourth angle θ4. A length of the first inclined surface 172a may be greater than a length of the second inclined surface 172b. A length of the fourth inclined surface 172d may be greater than a length of the third inclined surface 172c. The third inclined surface 172c may face the first inclined surface 172a, and the second inclined surface 172b may face the fourth inclined surface 172d.

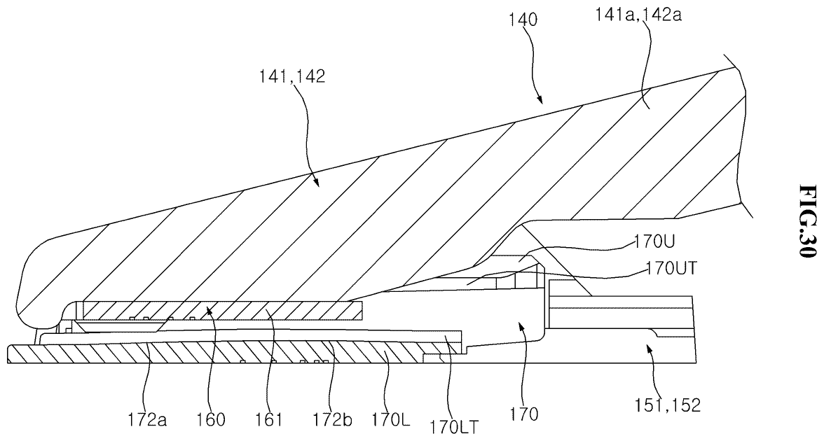

Referring to FIG. 30 along with FIG. 26, the slide bracket 160 to which the wing 140 is coupled may be inserted into or coupled to the guide cover 170 and the sliding mount 151, 152. As the wings 151 and 152 move while pivoting about the driving module 130, the slide bracket 160 may move on the guide cover 170 in a longitudinal direction of the wing 140.

When the wing 140 causes the display panel 110 to change from a flat state to a curved state, the slide bracket 160 may move from the first inclined surface 172a to the second inclined surface 172b. When the wing 140 causes the display panel 110 to change from a curved state with a predetermined curvature to a flat state, the slide bracket 160 may move from the second inclined surface 172b to the first inclined surface 172a.

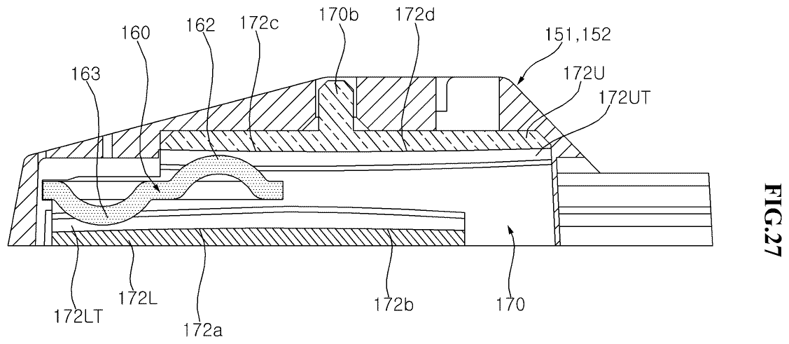

Referring also to FIG. 27, while the wing 140 causes the display panel 110 to change from a flat state to a curved state, the front protrusion 163 of the slide bracket 160 may slide in contact with the lower trench 172LT. The front protrusion 163 may press and rub against the lower trench 172LT. The rear protrusion 162 may slide in contact with the upper trench 172UT or may slide while being supported by the upper trench 172UT.

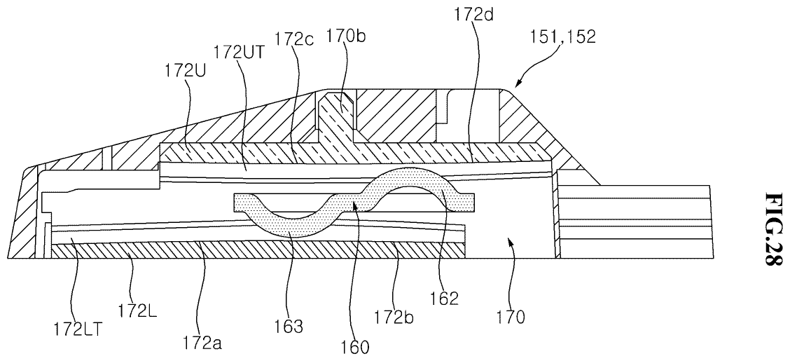

Referring also to FIG. 28, while the wing 140 causes the display panel 110 to change from a curved state with a predetermined curvature to a flat state, the front protrusion 163 of the slide bracket 160 may slide in contact with the lower trench 172LT or may slide while being supported by the lower trench 172LT. The rear protrusion 162 may slide in contact with the upper trench 172UT or may slide while being supported by the upper trench 172UT.

Accordingly, when the display panel 110 is curved, the curved curvature of the display panel 110 may become a constant curvature with a predetermined curvature or a curvature close to the constant curvature.

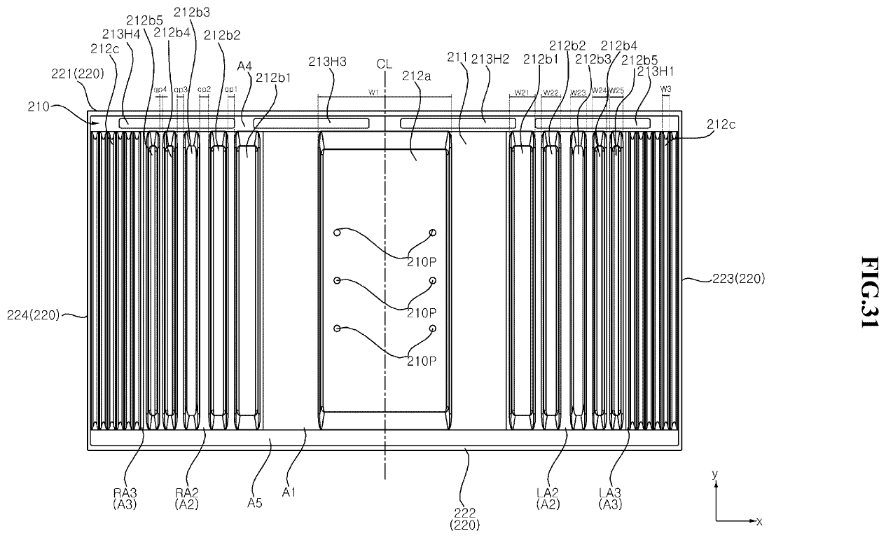

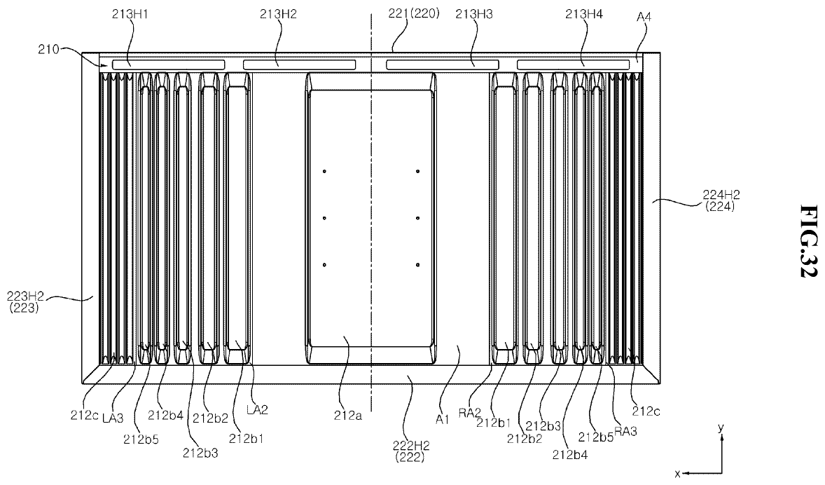

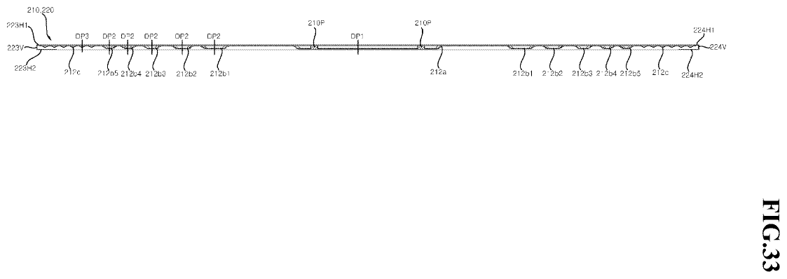

Referring to FIGS. 31, 32 and 33, the plate 120 (see FIG. 2) may be referred to as a bottom cover 120, 200 or a rear cover 120, 200. The bottom cover 200 may include an inner plate 210. FIG. 31 illustrates a front surface of the inner plate 210, and FIG. 32 illustrates a rear surface of the inner plate 210. For example, the inner plate 210 may include a metal, and may be a thin plate. The inner plate 210 may be flexible in a direction in which the display panel 110 is curved.

The inner plate 210 may include a plate part 211 and a forming part 212. The plate part 211 may be a thin plate extending in a flat manner. The plate part 211 may face the display panel 110, and may have a size and shape corresponding to the display panel 110. The plate part 211 may have long sides facing the long sides LS1 and LS2 of the display panel 110, and short sides facing the short sides SS1 and SS2 of the display panel 110.

The forming part 212 may be formed on the plate part 211. The forming part 212 may be formed by being recessed rearward from a front surface of the plate part 211. The forming part 212 may be elongated in a direction intersecting the direction in which the inner plate 210 is curved. The forming part 212 may be elongated along one side of the inner plate 210. The forming part 212 may be elongated in a longitudinal direction of the short side of the plate part 211. The forming part 212 may be elongated vertically.

The inner plate 210 may include a first area A1 that has a vertical center line CL, a second area A2 that is adjacent to the first area A1, and a third area A3 that is adjacent to the second area A2 and opposite the first area A1 with respect to the second area A2. The left area and the right area may be symmetric with respect to the center line CL of the inner plate 210. The second area A2 may include a left second area LA2 located to the left of the first area A1, and a right second area RA2 located to the right of the first area A1. The third area A3 may include a left third area LA3 located to the left of the first area A1, and a right third area RA3 located to the right of the first area A1. The left third area LA3 may be adjacent to the left second area LA2, and the right third area LA3 may be adjacent to the right second area RA2. The first area A1 may be an area where the least deformation occurs when the display panel 110 and/or the inner plate 210 is curved. The second area A2 may be an area where the most deformation occurs when the display panel 110 and/or the inner plate 210 is curved. The third area A3 may be an area supporting a lateral side (sides) of the display panel 110 or an area adjacent to the area supporting the lateral side of the display panel 110.

A plurality of forming parts 212 may be provided. The plurality of forming parts 212 may include a first forming part 212a. The first forming part 212a may be positioned in the first area A1. The first forming part 212a may be positioned at a central portion of the first area A1, and may be formed symmetrically with respect to the center line CL of the inner plate 210. The first forming part 212a may have a first width W1 and a first depth Dp1. Here, the width of the forming part 212 may be the width in the left-and-right direction, the horizontal direction, and/or a longitudinal direction of the long side of the plate part 211, and the depth of the forming part 212 may be the depth in the front-and-rear direction and/or a thickness direction of the inner plate 210.

As the first forming part 212a is formed with a large width in the area A1 that experiences the least deformation when the inner plate 210 is curved, the display panel 110 and the bottom cover 200 may be curved with a constant curvature or a curvature close to the constant curvature.

The plurality of forming parts 212 may include a second forming part 212b. The second forming part 212b may be positioned in the second area A2. The second forming part 212 may have a second width W2 and a second depth Dp2. The second width W2 may be less than the first width W1. The second depth Dp2 may be less than the first depth Dp1. A plurality of second forming parts 212b may be provided. The plurality of second forming parts 212b may be arranged to be spaced apart from each other in the horizontal direction.

The plurality of second forming parts 212b may have different widths. The plurality of second forming parts 212b may have larger widths as they are closer to the first area A1. The plurality of third forming parts 212b may have smaller widths as they are closer to the third area A3. The widths of the plurality of second forming parts 212b may become smaller from the first area A1 to the third area A3. For example, the plurality of second forming parts 212b may include a 21^{st} forming part 212b1, a 22^{nd} forming part 212b2, a 23^{rd} forming part 212b3, a 24^{th} forming part 212b4, and a 25^{th} forming part 212b5 sequentially arranged along a direction from the first area A1 to the third area A3. Among the plurality of second forming parts 212b, the 21^{st} forming part 212b1 may be closest to the first area A1. Among the plurality of second forming parts 212b, the 25^{th} forming part 212b5 may be closest to the third area A3. A width W21 of the 21^{st} forming part 212b1 may be greater than a width W22 of the 22^{nd} forming part 212b2. The width W22 of the 22^{nd} forming part 212b2 may be greater than a width W23 of the 23^{rd} forming part 212b3. The width W23 of the 23^{rd} forming part 212b3 may be greater than a width W24 of the 24^{th} forming part 212b4. The width W24 of the 24^{th} forming part 212b4 may be equal to a width W25 of the 25^{th} forming part 212b5. Alternatively, the width W24 of the 24^{th} forming part 212b4 may be greater than the width W25 of the 25^{th} forming part 212b5.

The plurality of second forming parts 212b may have the same depth. Alternatively, the plurality of second forming parts 212b may have different depths.

The plurality of second forming parts 212b may be spaced apart at equal intervals. Alternatively, the plurality of second forming parts 212b may be spaced apart at different intervals. For example, the 21^{st} forming part 212b1 and the 22^{nd} forming part 212b2 may be spaced apart from each other by a first interval ap1, the 22^{nd} forming part 212b2 and the 23^{rd} forming part 212b3 may be spaced apart from each other by a second interval ap2, the 23^{rd} forming part 212b3 and the 24^{th} forming part 212b4 may be spaced apart from each other by a third interval ap3, and the 24^{th} forming part 212b4 and the 25^{th} forming part 212b5 may be spaced apart from each other by a fourth interval ap4. The first interval ap1 may be less than the second interval ap2. The first interval ap1 may be equal to the third interval ap3 and greater than the fourth interval ap4.

As the second forming part 212b is formed with various widths and depths in the area A2 that experiences the most deformation when the inner plate 210 is curved, the display panel 110 and the bottom cover 200 may be curved with a constant curvature or a curvature close to the constant curvature.

The plurality of forming parts 212 may include a third forming part 212c. The third forming part 212c may be positioned in the third area A3. The third forming part 212c may have a third width W3 and a third depth Dp3. The third width W3 may be less than the second width W2. The third depth Dp3 may be less than the second depth Dp2. A plurality of third forming parts 212c may be provided. The plurality of third forming parts 212c may be arranged to be spaced apart from each other in the horizontal direction. The plurality of third forming parts 212c may be spaced apart at equal intervals. The plurality of third forming parts 212c may have the same width and depth. For example, the plurality of third forming parts 212c may include five third forming parts 212c. The third forming part 212c may ensure the rigidity of a lateral portion of the inner plate 210, thereby allowing the display panel 110 and the bottom cover 200 to be curved with a constant curvature or a curvature close to the constant curvature.

Accordingly, the display panel 110 and the bottom cover 200 may be curved with a constant curvature or a curvature close to the constant curvature.

The first to third forming parts 212a, 222b, and 222c may have the same length. The length of the forming part 212 may be the length in the up-and-down direction, the vertical direction, and/or the longitudinal direction of the short side of the plate part 211.

The number of the plurality of third forming parts 212c may be greater than that of the plurality of second forming parts 212b. The number of the plurality of second forming parts 212b may be greater than that of the first forming part 212a. For example, one first forming part 212a may be provided, five second forming parts 212b may be provided, and six third forming parts 212c may be provided. This allows the display panel 110 and the bottom cover 200 to be curved with a constant curvature or a curvature close to the constant curvature. In addition, as the third forming parts 212c are most numerous, it is possible to reinforce the rigidity of the short sides of the inner plate 210.

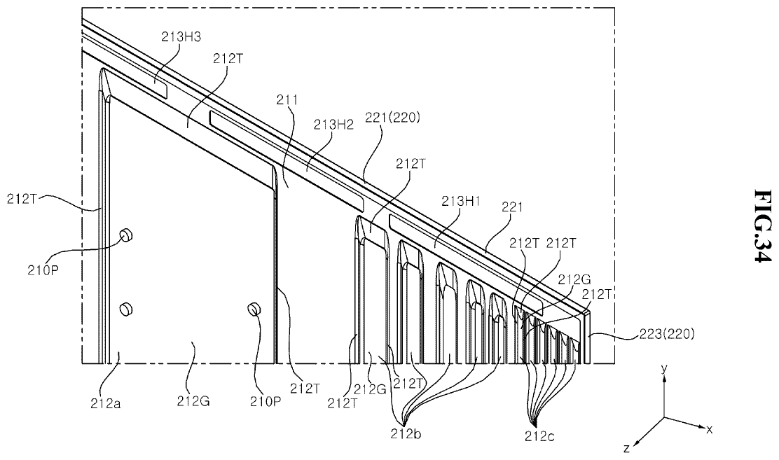

Referring to FIG. 34, the forming part 212 may include a groove part 212G and a tapered (or taper) part 212T. The groove part 212G may be formed by being pressed rearward from the plate part 211. The tapered part 212T may be a portion that connects the groove part 212G and the plate part 211. The tapered part 212T may connect an edge of the groove part 212G and the plate part 211. The tapered part 212T may be formed in an inclined manner. The tapered part 212T may include, at least in part, a curved surface. The tapered part 212T may be formed to be inclined upwardly from the groove part 212G to the plate part 211.

The groove part 212G and the tapered part 212T may be formed on each of the first forming part 212a, the second forming part 212b, and the third forming part 212c.

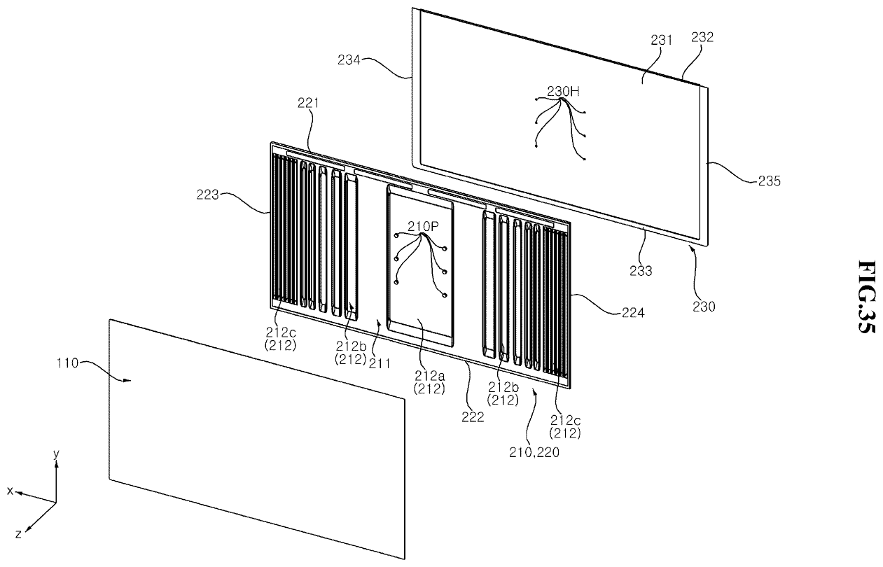

Referring to FIGS. 35, 36 and 37 along with FIG. 31, the inner plate 210 may include a fourth area A4. The fourth area A4 may be adjacent to the first to third areas A1, A2, and A3. The fourth area A4 may be positioned over the first to third areas A1, A2, and A3. The fourth area A4 may be elongated along the longitudinal direction of the long side of the plate part 211. The fourth area A4 may be parallel to the display panel 110, and an upper end of the display panel 110 may be coupled thereto. An adhesive member may be disposed between the fourth area A4 and the display panel 110.

A hole 213H may be formed in the fourth area A4. The hole 213H may be a long hole elongated in the left-and-right direction. The hole 213H may be provided in plurality, and the plurality of holes 213H may be spaced apart from each other along a longitudinal direction of the long side of the inner plate 210. For example, the hole 213H may include a first hole 213H1, a second hole 213H2, a third hole 213H3, and a fourth hole 213H4. The hole 213H may allow the bottom cover 200 including the inner plate 210 and/or the outer plate 210 and the display panel 110 to be curved with a constant curvature or a curvature close to the constant curvature.

The inner plate 210 may include a fifth area A5. The fifth area A5 may be adjacent to the first to third areas A1, A2 and A3. The fifth area A5 may be positioned beneath the first to third areas A1, A2 and A3. The fifth area A5 may be opposite the fourth area A4 with respect to the first to third areas A1, A2 and A3. The fifth area A5 may be elongated along the longitudinal direction of the long side of the plate part 211. The fifth area A5 may be parallel to the display panel 110, and a lower end of the display panel 110 may be coupled thereto. An adhesive member may be disposed between the fifth area A5 and the display panel 110.

Both lateral ends of the display panel 110 may be coupled to the third area A3 of the inner plate 210. The left end of the display panel 110 may be coupled to the left third area LA3, and the right end of the display panel 110 may be coupled to the right third area RA3. The left end of the display panel 110 may be coupled to the outermost part of the left third area LA3, and the right end of the display panel 110 may be coupled to the outermost part of the right third area RA3. An adhesive member may be disposed between the third area A3 of the inner plate 210 and the display panel 110.

The bottom cover 200 may include a side frame 220. The side frame 220 may define a rectangular edge. The side frame 220 may extend from the inner plate 210. The side frame 220 may be formed as one body with the inner plate 210.

The side frame 220 may include a first side frame 221. The first side frame 221 may be adjacent to the first long side LS1 of the display panel 110. The first side frame 221 may extend from the fourth area A4 of the inner plate 210. The first side frame 221 may include a first horizontal part 221H and a first vertical part 221V. The first horizontal part 221H may extend upward from the fourth area A4. The first horizontal part 221H may protrude forward relative to the fourth area A4, and may form a step with the fourth area A4. The first horizontal part 221H may be pressed forward so as to protrude from the fourth area A4. The first horizontal part 221H may face the first long side LS1 of the display panel 110. The first horizontal part 221H may extend in an elongated manner along the first long side LS1 of the display panel 110. The first vertical part 221V may extend in a direction intersecting the extension direction of the first horizontal part 221H, and may be formed at an edge of the first horizontal part 221H. The first vertical part 221V may extend in an elongated manner along the edge of the first horizontal part 221H.

The side frame 220 may include a second side frame 222. The second side frame 222 may be adjacent to the second long side LS2 of the display panel 110. The second side frame 222 may extend from the fifth area A5 of the inner plate 210. The second side frame 222 may be opposite the first side frame 221 with respect to the display panel 110. The second side frame 222 may include a 21^{st} horizontal part 222H1, a second vertical part 222V, and a 22^{nd} horizontal part 221H2. The 21^{st} horizontal part 222H1 may extend upward from the fifth area A5. The 21^{st} horizontal part 222H1 may protrude forward relative to the fifth area A5, and may form a step with the fifth area A5. The 21^{st} horizontal part 222H1 may be pressed forward so as to protrude from the fifth area A5. The 21^{st} horizontal part 222H1 may face the second long side LS2 of the display panel 110. The 21^{st} horizontal part 222H1 may extend in an elongated manner along the second long side LS2 of the display panel 110. The second vertical part 222V may extend in a direction intersecting the extension direction of the 21^{st} horizontal part 222H1, and may be formed at an edge of the 21^{st} horizontal part 222H2. The second vertical part 222V may extend in an elongated manner along the edge of the 21^{st} horizontal part 222H2. The 22^{nd} horizontal part 222H2 may be positioned behind the 21st horizontal part 222H1, and may face the 21st horizontal part 222H1. The 22^{nd} horizontal part 222H2 may extend in a direction parallel to the extension direction of the 21^{st} horizontal part 222H1. The 22^{nd} horizontal part 222H2 may be connected to the second vertical part 222V. That is, the second vertical part 222V may connect the 21^{st} horizontal part 222H1 and the 22^{nd} horizontal part 222H2, the 21^{st} horizontal part 222H1 may be connected to a front edge of the second vertical part 222V, and the 22^{nd} horizontal part 222H2 may be connected to a rear edge of the second vertical part 222V. The 21^{st} horizontal part 222H1 may extend upward from the rear edge of the second vertical part 222V by a first length, and the 22^{nd} horizontal part 222H2 may extend upward from the rear edge of the second vertical part 222V by a second length. In this case, the second length may be greater than the first length.

The side frame 220 may include a third side frame 223. The third side frame 223 may be adjacent to the first short side SS1 of the display panel 110. The third side frame 223 may extend from the left third area LA3 of the inner plate 210. The third side frame 223 may include a 31^{st} horizontal part 223H1, a 32^{nd} horizontal part 223H2, and a third vertical part 223V.

The 31^{st} horizontal part 223H1 may extend from the left third area LA3. The 31^{st} horizontal part 223H1 may protrude forward relative to the left third area LA3, and may form a step with the left third area LA3. The 31^{st} horizontal part 223H1 may be pressed forward so as to protrude from the left third area LA3. The 31^{st} horizontal part 223H1 may face the first short side SS1 of the display panel 110. The 31^{st} horizontal part 223H1 may extend in an elongated manner along the first short side SS1 of the display panel 110. The third vertical part 223V may extend in a direction intersecting the extension direction of the 31^{st} horizontal part 223H1, and may be formed at an edge of the 31^{st} horizontal part 223H1. The third vertical part 223V may extend in an elongated manner along the edge of the 31^{st} horizontal part 223H1. The 32^{nd} horizontal part 223H2 may be positioned behind the 31^{st} horizontal part 223H1, and may face the 31^{st} horizontal part 223H1. The 32^{nd} horizontal part 223H2 may extend in a direction parallel to the extension direction of the 31^{st} horizontal part 223H1. The 32^{nd} horizontal part 223H2 may be connected to the third vertical part 223V. That is, the third vertical part 223V may connect the 31^{st} horizontal part 223H1 and the 32^{nd} horizontal part 223H2, the 31^{st} horizontal part 223H1 may be connected to a front edge of the third vertical part 223V, and the 32^{nd} horizontal part 223H2 may be connected to a rear edge of the third vertical part 222V. The 31^{st} horizontal part 223H1 may extend to the left from the rear edge of the third vertical part 223V by a first length, and the 32^{nd} horizontal part 223H2 may extend to the right from the rear edge of the third vertical part 223V by a second length. In this case, the second length may be greater than the first length.

The side frame 220 may include a fourth side frame 224. The fourth side frame 224 may be adjacent to the second short side SS2 of the display panel 110. The fourth side frame 224 may extend from the right third area RA3 of the inner plate 210. The fourth side frame 224 may include a 41^{st} horizontal part 224H1, a 42^{nd} horizontal part 224H2, and a fourth vertical part 224V.

The 41^{st} horizontal part 224H1 may extend from the right third area RA3. The 41^{st} horizontal part 224H1 may protrude forward relative to the right third area RA3, and may form a step with the right third area RA3. The 41^{st} horizontal part 224H1 may be pressed forward so as to protrude from the right third area RA3. The 41^{st} horizontal part 224H1 may face the second short side SS2 of the display panel 110. The 41^{st} horizontal part 224H1 may extend in an elongated manner along the second short side SS2 of the display panel 110. The fourth vertical part 224V may extend in a direction intersecting the extension direction of the 41^{st} horizontal part 224H1, and may be formed at an edge of the 41^{st} horizontal part 224H1. The fourth vertical part 224V may extend in an elongated manner along the edge of the 41^{st} horizontal part 224H1. The 42^{nd} horizontal part 224H2 may be positioned behind the 41^{st} horizontal part 224H1, and may face the 41^{st} horizontal part 224H1. The 42^{nd} horizontal part 224H2 may extend in a direction parallel to the extension direction of the 41^{st} horizontal part 224H1. The 42^{nd} horizontal part 224H2 may be connected to the fourth vertical part 224V. That is, the fourth vertical part 224V may connect the 41^{st} horizontal part 224H1 and the 42^{nd} horizontal part 224H2, the 41^{st} horizontal part 224H1 may be connected to a front edge of the fourth vertical part 224V, and the 42^{nd} horizontal part 224H2 may be connected to a rear edge of the fourth vertical part 224V. The 41^{st} horizontal part 224H1 may extend to the right from the rear edge of the fourth vertical part 224V by a first length, and the 42^{nd} horizontal part 224H2 may extend to the left from the rear edge of the fourth vertical part 224V by a second length. In this case, the second length may be greater than the first length.

The bottom cover 200 may include an outer plate 230. The outer plate 230 may be opposite the display panel 110 with respect to the inner plate 210. The outer plate 230 may be positioned behind the inner plate 210. The outer plate 230 may be coupled to the inner plate 210. The outer plate 230 may be coupled to the side frame 220. For example, the outer plate 230 may be a flexible thin metal plate. As another example, the outer plate 230 may be a flexible thin plastic plate.

The outer plate 230 may include a center part 231. The center part 231 may face the inner plate 230, and may be spaced rearward from the inner plate 230. The center part 231 may face the plate part 211, and may be parallel to the plate part 211. The center part 231 may be a thin rectangular plate with long sides and short sides.

The outer plate 230 may include an upper part 232. The upper part 232 may extend in a direction intersecting a longitudinal direction of the long side of the center part 231. The upper part 232 may be formed at an upper edge of the center part 231, and may be formed by being bent forward from the upper edge of the center part 231. The upper part 232 may be elongated along the longitudinal direction of the long side of the center part 231. The upper part 232 may be coupled to the first side frame 221. The upper part 232 may face the first vertical part 221V of the first side frame 221. The upper part 232 may be positioned under the first vertical part 221V of the first side frame 221, and may be coupled to the first vertical part 221V. An adhesive member may be disposed between the upper part 232 and the first vertical part 221V.

The outer plate 230 may include a lower part 233. The lower part 233 may be opposite the upper part 231 with respect to the center part 231. The lower part 233 may protrude by being pressed forward from a lower end of the center part 231. Alternatively, the lower part 233 may be fixed to the lower front of the center part 231. The lower part 233 may be a rectangular thin plate. The lower part 233 may extend along a longitudinal direction of the long side of the center part 231. The lower part 233 may be coupled to the second side frame 222. The lower part 233 may be disposed between the 21^{st} horizontal part 222H1 and the 22^{nd} horizontal part 222H2 of the second side frame 222, and may be coupled to the 22^{nd} horizontal part 222H2. An upper end of the 22^{nd} horizontal part 222H2 and the lower end of the center part 231 may face each other in the up-and-down direction. An adhesive member may be disposed between the lower part 233 and the 22^{nd} horizontal part 222H2.

The outer plate 230 may include a first side part 234. The first side part 234 may protrude by being pressed forward from a left end of the center part 231. Alternatively, the first side part 234 may be fixed to the front left of the center part 231. The first side part 234 may be a rectangular thin plate. The first side part 234 may extend along a longitudinal direction of the short side of the center part 231. The first side part 234 may be coupled to the third side frame 223. The first side part 234 may be disposed between the 31^{st} horizontal part 223H1 and the 32^{nd} horizontal part 223H2 of the third side frame 223, and may be coupled to the 32^{nd} horizontal part 223H2. A right end of the 32^{nd} horizontal part 223H2 and the left end of the center part 231 may face each other in the left-and-right direction. An adhesive member may be disposed between the first side part 234 and the 32^{nd} horizontal part 223H2.

The outer plate 230 may include a second side part 235. The second side part 235 may protrude by being pressed forward from a right end of the center part 231. Alternatively, the second side part 235 may be fixed to the front right of the center part 231. The second side part 235 may be a rectangular thin plate. The second side part 235 may extend along a longitudinal direction of the short side of the center part 231. The second side part 235 may be opposite the first side part 234 with respect to the center part 231. The second side part 235 may be coupled to the fourth side frame 224. The second side part 235 may be disposed between the 41^{st} horizontal part 224H1 and the 42^{nd} horizontal part 224H2 of the fourth side frame 224, and may be coupled to the 42^{nd} horizontal part 224H2. A right end of the 42^{nd} horizontal part 224H2 and the right end of the center part 231 may face each other in the left-and-right direction. An adhesive member may be disposed between the second side part 235 and the 42^{nd} horizontal part 224H2.

Accordingly, the side frame 220 may cover the sides of the display panel 110, and may space and fix the outer plate 230 rearward from the inner plate 210. Thus, a space for forming the forming part 212 of the inner plate 210 may be secured, and the bottom cover 200 including the inner plate 210 and/or the outer plate 210 and the display panel 110 may be curved with a constant curvature or a curvature close to the constant curvature.

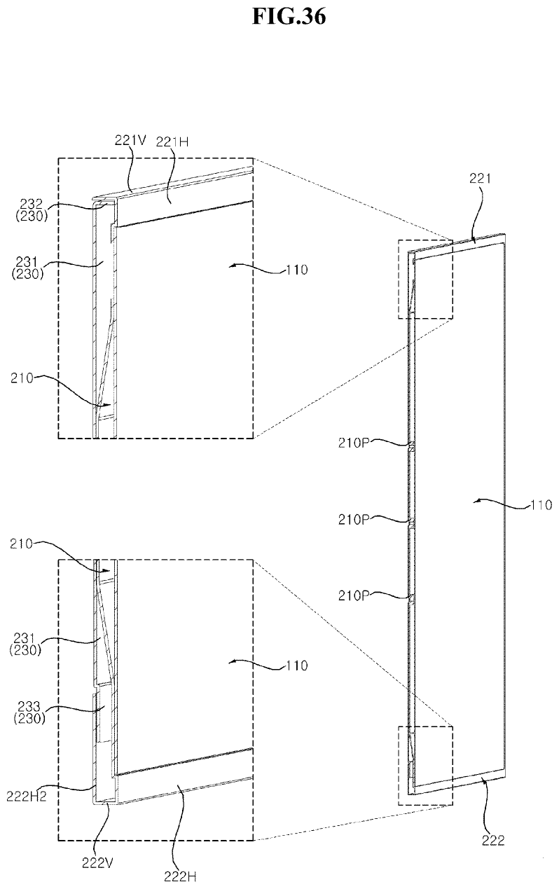

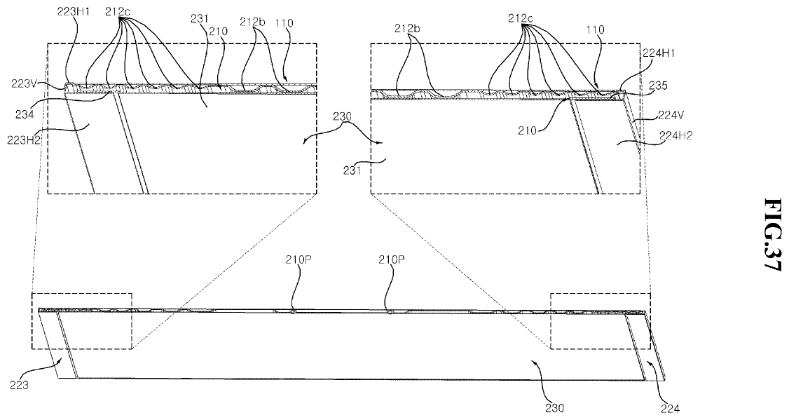

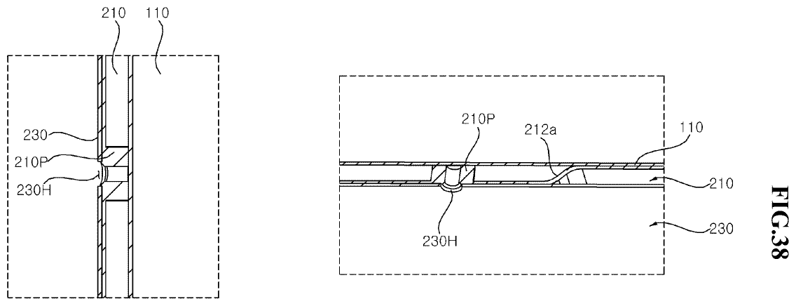

Referring to FIG. 36 and a left drawing of FIG. 38((a) of FIG. 38) or FIG. 37 and a right drawing of FIG. 38((b) of FIG. 38), the inner plate 210 may include a coupling protrusion 210P. The coupling protrusion 210P may be formed on the first forming part 212a. The coupling protrusion 210P may protrude forward from the first forming part 212a. The coupling protrusion 210P may have a height corresponding to the first depth Dp1 of the first forming part 212a. A plurality of coupling protrusions 210P may be provided. For example, the plurality of coupling protrusions 210P may be provided as six coupling protrusions 212ap, and may be spaced apart from each other. For example, the plurality of coupling protrusions 210P may be provided in two columns in the first forming part 212a, and each column may include three coupling protrusions 210P.

The outer plate 230 may include a hole 230H formed through the outer plate 230 in the front-and-rear direction. A plurality of holes 230H may be provided. The hole 230H and/or each of the plurality of holes 230H may be aligned with the coupling protrusion 210P. A fastening member may pass through the hole 230H of the outer plate 230 and be fastened to the coupling protrusion 210P. For example, the fastening member may be a PEM nut.

The coupling protrusion 210P may support the display panel 110 and the inner plate 210 so as to maintain a gap between the display panel 110 and the first forming part 212a, which is formed deeper and wider than the other forming parts. Accordingly, the bottom cover 200 including the inner plate 210 and/or the outer plate 210 and the display panel 110 may be curved with a constant curvature or a curvature close to the constant curvature.

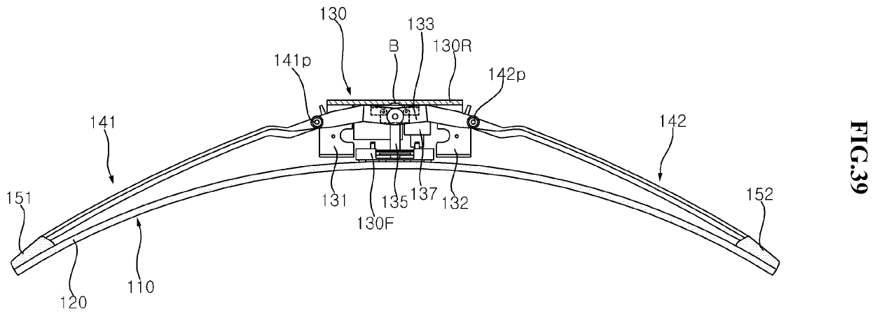

Referring to FIG. 39 along with FIG. 2, as the lead screw 135 is rotated by the torque provided by the motor 137, the flip frame 133 may move in the longitudinal direction of the lead screw 135, causing the wing 140 to pivot about the pivot shaft 141P, 142P.

When the wing 140 pivots, the slide bracket 160 may move on the sliding mount 151, 152 (see FIG. 26) and the guide cover 170 while pushing both short sides of the display panel 110 and the plate 120, causing the display panel 110 to be curved.

When the lead screw 135 is reversely rotated, the flip frame 133 may move in a reverse direction of the lead screw 135, causing the wing 140 to pivot about the pivot shaft 141P, 142P in an opposite direction.

When the wing 140 pivots in the opposite direction, the slide bracket 160 may move on the sliding mount 151, 152 and the guide cover 170 while pulling both short sides of the display panel 110 and the plate 120, causing the display panel 110 to be flat.

Referring to FIGS. 1 to 39, a display device may include: a flexible display panel 110; a bottom cover 200 positioned behind the display panel 110 and to which the display panel 110 is coupled; a driving module 130 disposed at a rear of the bottom cover 200 and including a moving block 134 configured to perform a reciprocating motion; a wing bracket 131, 132 adjacent to the driving module 130 and fixed to the rear of the bottom cover 200; and a wing 141, 142 elongated with a first end fixed to the moving block 134 and a second end coupled to the bottom cover 200, and pivotably coupled to the wing bracket 131, 132 between the first end and the second end. The bottom cover 200 may include: an inner plate 210 facing a rear surface of the display panel 110 and to which a lateral side of the display panel 100 is coupled. The inner plate 210 may include: a plate part 211 facing the rear surface of the display panel 110 and having a long side and a short side; and a forming part 212 formed by being pressed rearward from the plate part 211, the forming part 212 being elongated in a longitudinal direction of the short side.

The forming part 212 may be provided in plurality, and the plurality of forming parts 212 may be spaced apart from each other in a longitudinal direction of the long side, and may have different widths.

The inner plate 210 may include: a first area A1 having a vertical center line CL of the inner plate 210; a second area A2 adjacent to the first area A1; and a third area A3 that is adjacent to the second area A2 and opposite the first area A1 with respect to the second area A2. The forming part 212 may include: a first forming part 212a positioned in the first area A1 and having a first width W1; a second forming part 212b positioned in the second area A2 and having a second width W2 less than the first width W1; and a third forming part 212c positioned in the third area A3 and having a third width W3 less than the second width W2.

The first forming part 212a may have a first depth Dp1 in a thickness direction of the inner plate 210, the second forming part 212b may have a second depth Dp2 in the thickness direction that is less than the first depth Dp1, and the third forming part 212c may have a third depth Dp3 in the thickness direction that is less than the second depth Dp2.

The second forming part 212b may be provided in plurality. The plurality of second forming parts 212b may be sequentially arranged along a direction from the second area A2 to the third area A3. The plurality of second forming parts 212b may have widths, respectively, that become smaller as the plurality of second forming parts 212b are closer to the third area A3.

The third forming part 212c may be provided in plurality, and the plurality of third forming parts 212c may have a same width W3.

The first to third forming parts 212a, 212b and 212c may each be provided in plurality. A number of the third forming parts 212c may be greater than a number of the second forming parts 212b, and a number of the second forming parts 212b may be greater than a number of the first forming parts 212a.

The forming part 212 may include: a groove part 212G forming a step with the plate part 211; and a tapered part 212T that connects the plate part 211 and an edge of the groove part 212G and is formed in an inclined manner.

The inner plate 210 may include: a fourth area A4 adjacent to the first to third areas A1, A2 and A3 and to which a first end of the display panel 110 is coupled; a fifth area A5 adjacent to the first to third areas A1, A2 and A3, opposite the fourth area A4 with respect to the first to third areas A1, A2 and A3, and to which a second end of the display panel 110 is coupled; and a plurality of holes 213H1, 213H2, 213H3, and 213H4 formed in the fourth area A4 and spaced apart from each other along a longitudinal direction of the long side.

The bottom cover 200 may include a side frame 200 to support sides of the display panel 110. The side frame 220 may include: a first side frame 221 including a first horizontal part 221H that extends from the fourth area A4 of the inner plate 210 and is pressed forward relative to the fourth area A4 so as to form a step, and a first vertical part 221H that extends in a direction intersecting the first horizontal part 221H; and a second side frame 222 including a 21^{st} horizontal part 222H1 that extends from the fifth area A5 of the inner plate 210 and is pressed forward relative to the fifth area A5 so as to form a step, a second vertical part 222V that extends in a direction intersecting the 21^{st} horizontal part 222H1, and a 22^{nd} horizontal part 222H2 that extends in a direction intersecting the second vertical part 222V and faces the 21^{st} horizontal part 222H1. An upper side of the display panel 110 may face the first horizontal part 221H, and a lower side of the display panel 110 may face the 21^{st} horizontal part 222H1.

A height of the 22^{nd} horizontal part 222H2 may be greater than a height of the 21^{st} horizontal part 222H1.

The bottom cover 200 may include: a flexible outer plate 230 facing the inner plate 210 at a rear of the inner plate 210 and coupled to the inner plate 210. The outer plate 230 may include: a center plate 231 facing the inner plate 210 and spaced rearward from the inner plate 210; an upper part 232 extending forward from an upper end of the center part 231, facing the first vertical part 221V, and coupled to the first vertical part 221V; and a lower part 233 coupled to a lower end of the center part 231, disposed between the 21^{st} horizontal part 222H1 and the 22^{nd} horizontal part 222H2, and coupled to the 22^{nd} horizontal part 222H2.

The inner plate 210 may include: a coupling protrusion 210P protruding forward from the inner plate 210, the coupling protrusion 210P being positioned on the first forming part 212a. The outer plate 230 may include a hole 230H aligned with the coupling protrusion 210P.

The coupling protrusion 210P may have a height corresponding to a depth Dp1 of the first forming part 210P.

Certain embodiments or other embodiments of the disclosure described above are not mutually exclusive or distinct from each other. Any or all elements of the embodiments of the disclosure described above may be combined or combined with each other in configuration or function.

For example, a configuration “A” described in one embodiment of the disclosure and the drawings, and a configuration “B” described in another embodiment of the disclosure and the drawings may be combined with each other. Namely, although the combination between the configurations is not directly described, the combination is possible except in the case where it is described that the combination is impossible.

The above detailed description is to be construed in all aspects as illustrative and not restrictive. The scope of the present disclosure should be determined by reasonable interpretation of the appended claims, and all changes coming within the equivalency range of the present disclosure are intended to be embraced in the scope of the present disclosure.

1. A display device comprising:
a flexible display panel;
a bottom cover positioned behind the display panel and to which the display panel is coupled;
a driving module disposed at a rear of the bottom cover, the driving module including a moving block configured to perform a reciprocating motion;
a wing bracket adjacent to the driving module and fixed to the rear of the bottom cover; and
a wing elongated with a first end fixed to the moving block and a second end coupled to the bottom cover, the wing being pivotably coupled to the wing bracket between the first end and the second end,
wherein the bottom cover comprises an inner plate facing a rear surface of the display panel and to which a lateral side of the display panel is coupled, and
wherein the inner plate comprises:
a plate part facing the rear surface of the display panel and having a long side and a short side; and
a forming part formed by being pressed rearward from the plate part, the forming part being elongated in a longitudinal direction of the short side.

2. The display device of claim 1, wherein the forming part is provided in plurality, and
wherein the plurality of forming parts are spaced apart from each other in a longitudinal direction of the long side and have different widths.

3. The display device of claim 1, wherein the inner plate includes:
a first area having a vertical center line of the inner plate;
a second area adjacent to the first area; and
a third area adjacent to the second area and opposite the first area with respect to the second area, and
wherein the forming part comprises:
a first forming part positioned in the first area and having a first width;
a second forming part positioned in the second area and having a second width less than the first width; and
a third forming part positioned in the third area and having a third width less than the second width.

4. The display device of claim 3, wherein:
the first forming part has a first depth in a thickness direction of the inner plate;
the second forming part has a second depth in the thickness direction that is less than the first depth; and
the third forming part has a third depth in the thickness direction that is less than the second depth.

5. The display device of claim 3, wherein the second forming part is provided in plurality,
wherein the plurality of second forming parts are sequentially arranged along a direction from the second area to the third area, and
wherein the plurality of second forming parts have widths, respectively, that become smaller as the plurality of second forming parts are closer to the third area.

6. The display device of claim 3, wherein the third forming part is provided in plurality, and
wherein the plurality of third forming parts have a same width.

7. The display device of claim 3, wherein the first to third forming parts are each provided in plurality,
wherein a number of the third forming parts is greater than a number of the second forming parts, and
wherein a number of the second forming parts is greater than a number of the first forming parts.

8. The display device of claim 1, wherein the forming part comprises:
a groove part forming a step with the plate part; and
a tapered part connecting the plate part and an edge of the groove part, the tapered part being formed in an inclined manner.

9. The display device of claim 3, wherein the inner plate includes:
a fourth area adjacent to the first to third areas and to which a first end of the display panel is coupled;
a fifth area adjacent to the first to third areas, opposite the fourth area with respect to the first to third areas, and to which a second end of the display panel is coupled; and
a plurality of holes formed in the fourth area and spaced apart from each other along a longitudinal direction of the long side.

10. The display device of claim 9, wherein the bottom cover comprises a side frame to support sides of the display panel,
wherein the side frame comprises:
a first side frame including a first horizontal part that extends from the fourth area of the inner plate and is pressed forward relative to the fourth area so as to form a step, and a first vertical part that extends in a direction intersecting the first horizontal part; and
a second side frame including a 21^{st} horizontal part that extends from the fifth area of the inner plate and is pressed forward relative to the fifth area so as to form a step, a second vertical part that extends in a direction intersecting the 21^{st} horizontal part, and a 22^{nd} horizontal part that extends in a direction intersecting the second vertical part and faces the 21^{st} horizontal part, and
wherein an upper side of the display panel faces the first horizontal part, and a lower side of the display panel faces the 21^{st} horizontal part.

11. The display device of claim 10, wherein a height of the 22^{nd} horizontal part is greater than a height of the 21^{st} horizontal part.

12. The display device of claim 10, wherein the bottom cover comprises:
a flexible outer plate facing the inner plate at a rear of the inner plate and coupled to the inner plate, and
wherein the outer plate comprises:
a center plate facing the inner plate and spaced rearward from the inner plate;
an upper part extending forward from an upper end of the center part, facing the first vertical part, and coupled to the first vertical part; and
a lower part coupled to a lower end of the center part, disposed between the 21^{st} horizontal part and the 22^{nd} horizontal part, and coupled to the 22^{nd} horizontal part.

13. The display device of claim 12, wherein the inner plate includes a coupling protrusion protruding forward from the inner plate, the coupling protrusion being positioned on the first forming part, and
wherein the outer plate includes a hole aligned with the coupling protrusion.

14. The display device of claim 13, wherein the coupling protrusion has a height corresponding to a depth of the first forming part.
